(19) United States
(12) Patent Application Publication
(10) Pub. No.: US 2024/0379831 A1
(43) Pub. Date: Nov. 14, 2024

(54) SEMICONDUCTOR DEVICE

(71) Applicant: Mitsubishi Electric Corporation, Tokyo (JP)

(72) Inventors: Kosuke SAKAGUCHI, Tokyo (JP); Shinya SONEDA, Tokyo (JP)

(73) Assignee: Mitsubishi Electric Corporation, Tokyo (JP)

(21) Appl. No.: 18/624,084

(22) Filed: Apr. 1, 2024

(30) Foreign Application Priority Data
May 9, 2023 (JP) 2023-077022

(51) Int. Cl. H01L 29/739; H01L 23/528; H01L 27/06; H01L 29/66; H01L 29/861

(52) U.S. Cl. CPC H01L 29/7397; H01L 23/528; H01L 27/0635; H01L 29/66348; H01L 29/861

(57) ABSTRACT

Prevented is local increase of a temperature of a chip in a semiconductor device including a diode region and an IGBT region. A semiconductor device includes a chip of an RC-IGBT including an IGBT region functioning as an IGBT and a plurality of diode regions functioning as a diode. The plurality of diode regions are disposed to form an island-like shape in an effective region which is a region made up of the IGBT region and the diode regions. When a length of one side of one of the diode regions is WD, an interval of the diode regions adjacent to each other is WI, a length of one side of the effective region is WC, and a thickness of the chip is t, satisfied are relationships of 2t<WD<5t, 2t<WI<5t, and WD+WI<WC/6.

### BACKGROUND OF THE INVENTION

### Field of the Invention

The present disclosure relates to a semiconductor device, and particularly relates to a semiconductor device including a diode region and an IGBT region.

### Description of the Background Art

Known is a reverse conducting insulated gate bipolar transistor (reverse conducting IGBT) (referred to as “RC-IGBT” hereinafter) as a semiconductor device having a structure in which an IGBT and a diode are formed in one semiconductor substrate (for example, Japanese Patent No. 5103830). The RC-IGBT also has a merit that an effective area can be reduced and a current density can be increased and high heat radiation properties are achieved compared with a case where an IGBT and a diode are formed separately.

The RC-IGBT has a problem that a temperature (Tj) of a topmost surface of a chip locally gets high. It is considered that this is caused by an insufficient thermal exchange between a diode region and an IGBT region.

### SUMMARY

An object of the present disclosure is to prevent local increase of a temperature of a chip in a semiconductor device including a diode region and an IGBT region.

A semiconductor device according to the present disclosure includes a chip of a reverse conducting IGBT (RC-IGBT) including an IGBT region functioning as an insulated gate bipolar transistor (IGBT) and a plurality of diode regions functioning as a diode. The plurality of diode regions are disposed to form an island-like shape in an effective region which is a region made up of the IGBT region and the diode regions. When a length of one side of one of the diode regions is WD, an interval of the diode regions adjacent to each other is WI, a length of one side of the effective region is WC, and a thickness of the chip is t, satisfied are relationships of 2t<WD<5t, 2t<WI<5t, and WD+WI<WC/6.

According to the semiconductor device according to the present disclosure, heat radiation properties between the diode region and the IGBT region is improved, and local increase of a temperature of the chip can be prevented.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a chip of a semiconductor device according to an embodiment 1.

FIG. 2 is a diagram illustrating a temperature distribution in the chip of the semiconductor device according to the embodiment 1.

FIG. 3 is a diagram illustrating a temperature distribution in a chip of a semiconductor device according to a comparison example.

FIG. 4 is a diagram of a short-circuit withstand time of the semiconductor device according to the embodiment 1 and the semiconductor device according to the comparison example.

FIG. 5 is a plan view of an IGBT region in the semiconductor device according to the embodiment 1.

FIG. 6 is a cross-sectional view of the IGBT region in the semiconductor device according to the embodiment 1.

FIG. 7 is a cross-sectional view of the IGBT region in the semiconductor device according to the embodiment 1.

FIG. 8 is a plan view of a diode region in the semiconductor device according to the embodiment 1.

FIG. 9 is a cross-sectional view of the diode region in the semiconductor device according to the embodiment 1.

FIG. 10 is a cross-sectional view of the diode region in the semiconductor device according to the embodiment 1.

FIG. 11 is a cross-sectional view of a boundary between the IGBT region and the diode region in the semiconductor device according to the embodiment 1.

FIG. 12 is a cross-sectional view of a terminal region in the semiconductor device according to the embodiment 1.

FIG. 13 is a diagram for explaining a method of manufacturing the semiconductor device according to the embodiment 1.

FIG. 14 is a diagram for explaining a method of manufacturing the semiconductor device according to the embodiment 1.

FIG. 15 is a diagram for explaining a method of manufacturing the semiconductor device according to the embodiment 1.

FIG. 16 is a diagram for explaining a method of manufacturing the semiconductor device according to the embodiment 1.

FIG. 17 is a diagram for explaining a method of manufacturing the semiconductor device according to the embodiment 1.

FIG. 18 is a diagram for explaining a method of manufacturing the semiconductor device according to the embodiment 1.

FIG. 19 is a diagram for explaining a method of manufacturing the semiconductor device according to the embodiment 1.

FIG. 20 is a diagram for explaining a method of manufacturing the semiconductor device according to the embodiment 1.

FIG. 21 is a diagram for explaining a method of manufacturing the semiconductor device according to the embodiment 1.

FIG. 22 is a diagram for explaining a method of manufacturing the semiconductor device according to the embodiment 1.

FIG. 23 is a diagram for explaining a method of manufacturing the semiconductor device according to the embodiment 1.

FIG. 24 is a diagram for explaining a method of manufacturing the semiconductor device according to the embodiment 1.

FIG. 25 is a plan view of a semiconductor device according to an embodiment 2.

FIG. 26 is a plan view of a semiconductor device according to an embodiment 3.

FIG. 27 is a diagram for explaining a semiconductor device according to an embodiment 4.

FIG. 28 is a diagram for explaining a configuration of a semiconductor device according to an embodiment 5.

FIG. 29 is a cross-sectional view of a boundary between an IGBT region and a diode region in a semiconductor device according to an embodiment 6.

### DESCRIPTION OF THE PREFERRED EMBODIMENTS

In the description hereinafter, an n type and a p type indicate a conductivity type of a semiconductor, and a first conductivity type is an n type and a second conductivity type is a p type in the present disclosure, however, the first conductivity type may be a p type, and the second conductivity type may be an n type. An n⁻ type indicates that an impurity concentration thereof is lower than that of the n type, and an n⁺ type indicates that an impurity concentration thereof is higher than that of the n type. In the similar manner, a p⁻ type indicates that an impurity concentration thereof is lower than that of the p type, and a p⁺ type indicates that an impurity concentration thereof is higher than that of the p type.

A degree of an impurity concentration of each region is regulated by a peak concentration. That is to say, a region having a high (or low) impurity concentration indicates a region having a high (or low) peak concentration of impurity.

### Embodiment 1

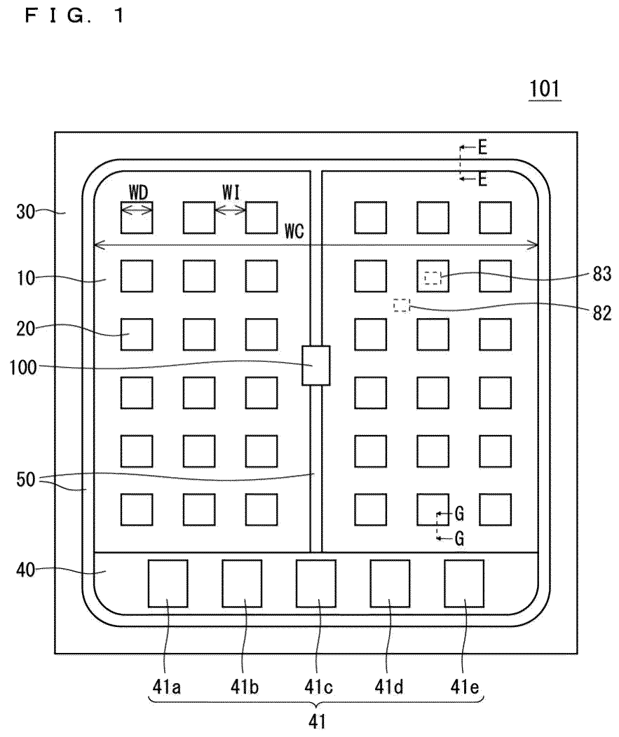

FIG. 1 is a plan view of a chip of a reverse conducting insulated gate bipolar transistor (reverse conducting IGBT) (referred to as “RC-IGBT” hereinafter) as a semiconductor device according to an embodiment 1.

A semiconductor device 101 includes an IGBT region 10 functioning as an IGBT and a diode region 20 functioning as a diode in one semiconductor device. The plurality of diode regions 20 are disposed side by side in a vertical direction and a lateral direction in the semiconductor device, and are surrounded by the IGBT region 10. That is to say, the plurality of diode regions 20 are provided to form an island-like shape in the IGBT region 10. The RC-IGBT having such a configuration is referred to as “an island-type RC-IGBT”.

In the semiconductor device 101 in FIG. 1, diode regions 20 are provided in a matrix of six rows in a right-left direction on a paper sheet and six rows in a vertical direction on a paper sheet in the IGBT region 10. However, the number and the arrangement of the diode regions 20 are not limited thereto. Any configuration is applicable as long as the plurality of diode regions 20 are provided in a scattered manner to satisfy conditions described hereinafter in the IGBT region 10 and each diode region 20 is surrounded by the IGBT region 10. A region made up of the IGBT region 10 and the diode region 20 is referred to as “a cell region” or “an effective region”. The number of diode regions 20 is referred to as “a division number” in some cases.

The semiconductor device 101 in FIG. 1 includes a temperature sensing diode 100 disposed in a center of the IGBT region 10 in a plan view. A pad region 40 is provided adjacent to a lower side of the IGBT region 10 on a paper sheet, and various type of control pad 41 for controlling the semiconductor device 101 are disposed in the pad region 40. An IGBT cell or a diode cell may be provided also in the pad region 40.

Illustrated in the pad region 40 in FIG. 1 as an example of the control pad 41 are a current sensing pad 41a, a kelvin emitter pad 41b, a gate pad 41c, and a pair of temperature sensing diode pads 41d and 41e.

The current sensing pad 41a is a control pad for sensing current flowing in a cell region in the semiconductor device 101. The current sensing pad 41a is electrically connected to the IGBT cell or the diode cell in a part of the cell region so that one severalth to one several-tens-thousandth of current flowing in the whole main cell flows in the current sensing pad 41a when the current flows in the cell region in the semiconductor device 101.

Gate drive voltage controlling ON and OFF of the semiconductor device 101 is applied to the Kelvin emitter pad 41b and the gate pad 41c. The Kelvin emitter pad 41b is electrically connected to a p-type base layer and an n⁺-type emitter layer of the IGBT cell. The gate pad 41c is electrically connected to a gate trench electrode of the IGBT cell. The Kelvin emitter pad 41b and the p-type base layer may be electrically connected via a p⁺-type contact layer.

The temperature sensing diode pad 41d is connected to one of an anode and a cathode of the temperature sensing diode 100, and the temperature sensing diode pad 41e is connected to the other one of the anode and the cathode of the temperature sensing diode 100. A voltage difference corresponding to a temperature of the temperature sensing diode 100 occurs in the temperature sensing diode pads 41d and 41e. A temperature of the semiconductor device 101 can be measured by measuring the voltage difference of the temperature sensing diode pads 41d and 41e.

A terminal region 30 for holding withstand voltage of the semiconductor device 101 is provided around the region the cell region and the pad region 40. The terminal region 30 can be provided by appropriately selecting a known withstand voltage holding structure. A field limiting ring (FLR) and a variation of lateral doping (VLD), for example, are known as the withstand voltage holding structure. The FLR is made by surrounding the region made up of the cell region and the pad region 40 with a ring-like p-type terminal well layer made up of a p-type semiconductor formed on a side of a first main surface as a front surface side of the semiconductor device 101. The VLD is made by surrounding the region made up of the cell region and the pad region 40 with a ring-like p-type terminal well layer having a concentration gradient formed on the side of the first main surface of the semiconductor device 101. The number of the ring-like p-type terminal well layers in the FLR and a concentration distribution of the ring-like p-type terminal well layer in the VLD are appropriately selected by a withstand voltage design of the semiconductor device 101. The p-type terminal well layer may be provided over almost the whole pad region 40.

A gate wiring region 50 is ensured in an outer surrounding part (inner surrounding part of the terminal region 30) of the region made up of the cell region and the pad region 40 and a region along a center line of the cell region in the semiconductor device 101 in FIG. 1. The gate wiring region 50 is a region for leading a gate wiring (also referred to as “a gate runner”) connecting a gate electrode of the IGBT and the gate pad 41c. The gate wiring region 50 in a part along the center line of the cell region is also used for leading the wiring connecting the temperature sensing diode 100 and the temperature sensing diode pads 41d and 41e.

The semiconductor device 101 according to the embodiment 1 is the RC-IGBT in which the plurality of island-like diode regions 20 are disposed in the effective region (cell region), and the diode regions 20 are disposed to satisfy the following conditions. That is to say, when a length of one side of the diode region 20 is WD, an interval of the diode regions 20 adjacent to each other is WI, a length of one side of the effective region is WC, and a thickness of the chip is t, the diode region 20 satisfies all of the following three expressions.

$$2 t < W D < 5 t \qquad expression ( 1 )$$

$$2 t < W I < 5 t \qquad expression ( 2 )$$

$$WD + WI < WC / 6. \qquad expression ( 3 )$$

According to the condition of the expression (3), a cycle (pitch) of the arrangement of diode regions 20 is set to be smaller than ⅙ of the length of one side of the effective region. Thus, six or more diode regions 20 are arranged along each side of the effective region. Accordingly, 36 or more diode regions 20 are provided in the effective region.

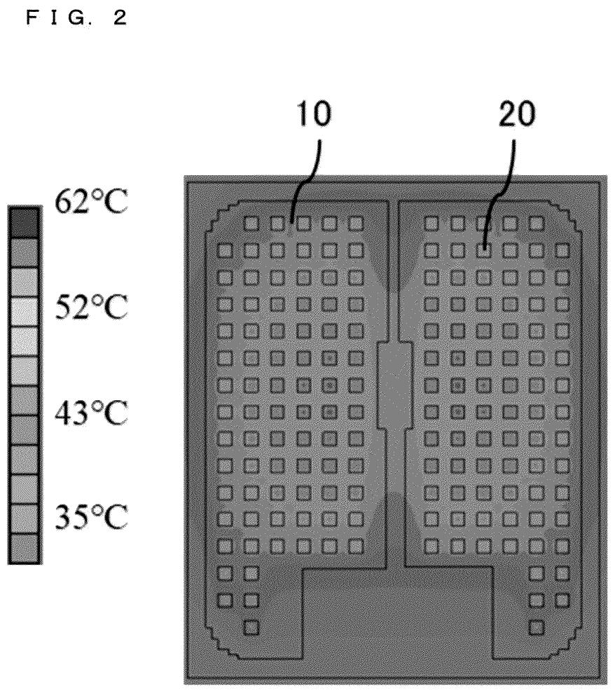

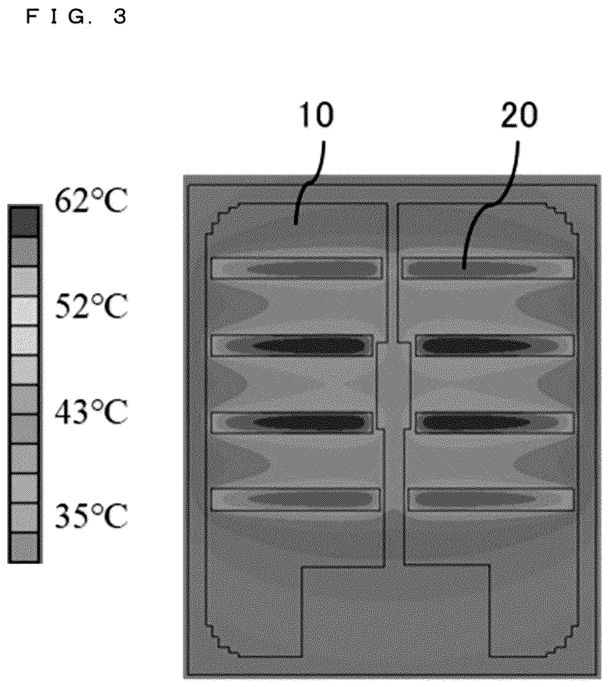

According to this configuration, a boundary length between the diode region 20 and the IGBT region 10 is increased, thus heat radiation properties between the diode region 20 and the IGBT region 10 is improved. FIG. 2 is a diagram illustrating a distribution of a temperature (Tj) of a topmost surface of the chip of the semiconductor device (the division number of the diode regions is 164) according to the embodiment 1 satisfying the expressions (1) to (3), and FIG. 3 is a diagram illustrating a distribution of Tj in a chip of a semiconductor device (the division number of the diode regions is 4) according to a comparison example which does not satisfy the expressions (1) to (3). Shown from a comparison of FIG. 2 and FIG. 3 is that a temperature is uniformized in the whole chip and Tj is low compared with the semiconductor device according to the comparison example.

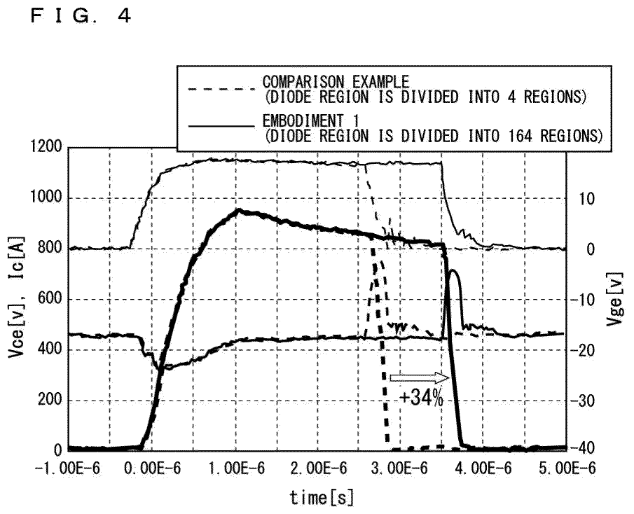

Reduction of Tj can contribute to increase of a short-circuit withstand time of the semiconductor device. FIG. 4 is a diagram comparing the short-circuit withstand time of the semiconductor device (the division number of the diode regions is 164) according to the embodiment 1 and the semiconductor device (the division number of the diode regions is four) according to the comparison example. It can be confirmed from FIG. 4 that the short-circuit withstand time is increased by approximately 35% in the semiconductor device according to the embodiment 1 compared with the semiconductor device according to the comparison example.

A structure that an insulating substrate provided with an IGBT chip is mounted to a base plate is general as a structure of a semiconductor device using an IGBT chip (including an RC-IGBT chip). A lower surface of the base plate serves as a cooling surface to cool the semiconductor device. Examples of thermal resistance defining a performance of such a semiconductor device include “Rth (j-c)” (case temperature reference) or “Rth (j-w)” (cooling water temperature reference) regulated by a difference between a temperature (Tj) of a topmost surface of a chip and a cooling water temperature or a temperature of a case. Conventionally, a chip area is increased or a surrounding member of a chip is changed generally to reduce thermal resistance of the semiconductor device. According to the semiconductor device according to the present embodiment, Tj can be reduced, thus the thermal resistance can be reduced without changing the area of the chip or changing the surrounding member. Thus, this configuration can contribute to improve a performance of the semiconductor device without increase of manufacturing cost.

Described hereinafter is an example of a structure of the semiconductor device as the RC-IGBT according to the embodiment 1.

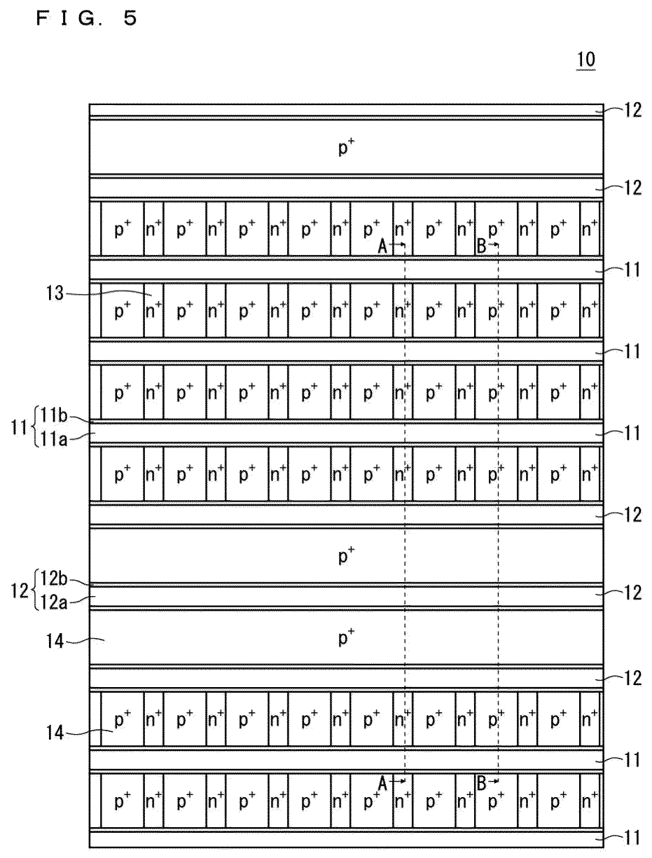

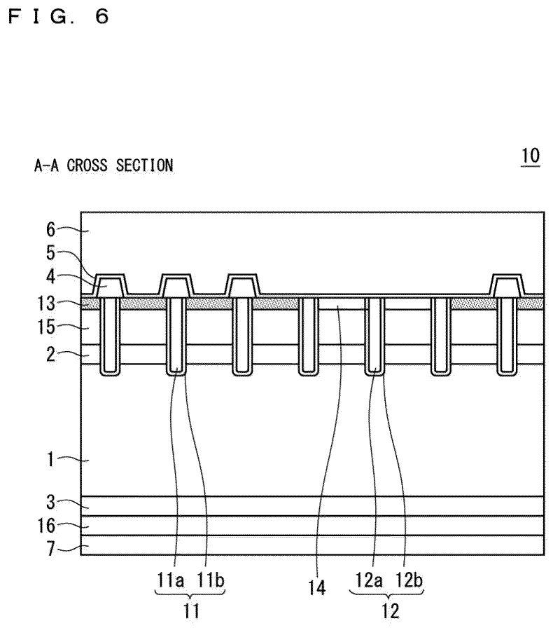

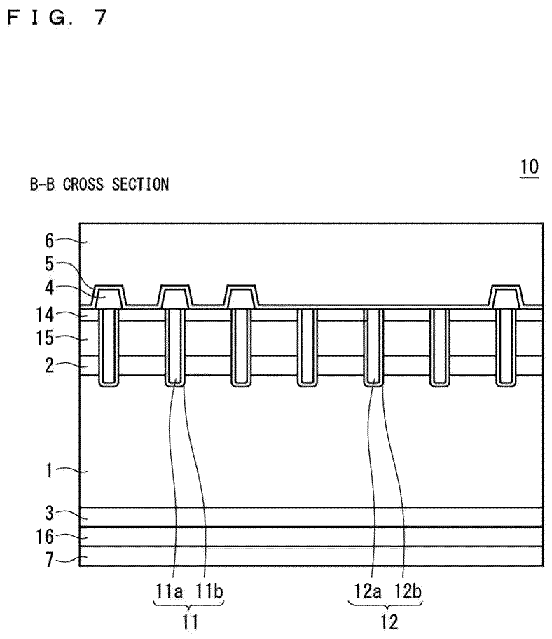

FIG. 5 is a partial enlarged plan view illustrating a configuration of the IGBT region 10 in the semiconductor device as the RC-IGBT. FIG. 6 and FIG. 7 are cross-sectional views each illustrating a configuration of the IGBT region in the semiconductor device as the RC-IGBT. FIG. 5 illustrates an enlarged view of a region surrounded by a broken line 82 in the semiconductor device 101 illustrated in FIG. 1. FIG. 6 is a cross-sectional view along a broken line A-A in the semiconductor device 101 illustrated in FIG. 5, and FIG. 7 is a cross-sectional view along a broken line B-B in the semiconductor device 101 illustrated in FIG. 5.

As illustrated in FIG. 5, an active trench gate 11 and a dummy trench gate 12 are provided in a stripe form in the IGBT region 10. FIG. 5 illustrates an example that the active trench gate 11 and the dummy trench gate 12 extend in a right-left direction on a paper sheet, however, there is no distinction between a longitudinal direction and a short-side direction of the IGBT region 10 in the island-type RC-IGBT, thus the active trench gate 11 and the dummy trench gate 12 may extend in an up-down direction on the paper sheet.

The active trench gate 11 has a configuration that a gate trench electrode 11a as a gate electrode is provided via a gate trench insulating film 11b as a gate insulating film in a trench formed in a semiconductor substrate. The dummy trench gate 12 has a configuration that a dummy trench electrode 12a is provided via a dummy trench insulating film 12b in a trench formed in a semiconductor substrate. The gate trench electrode 11a of the active trench gate 11 is electrically connected to the gate pad 41c. The dummy trench electrode 12a of the dummy trench gate 12 is electrically connected to an emitter electrode provided on a first main surface of the semiconductor device 101.

A material of the semiconductor substrate may be silicon or wide bandgap semiconductor such as silicon carbide (SiC). A semiconductor device formed using the wide bandgap semiconductor is excellent in an operation in high voltage, large current, and high temperature compared with a conventional semiconductor device using silicon. Silicon carbide, gallium nitride (GaN) series material, and diamond, for example, are applied as the wide bandgap semiconductor.

An n⁺-type emitter layer 13 is provided on both sides of the active trench gate 11 in a width direction to have contact with the gate trench insulating film 11b. The n⁺-type emitter layer 13 is a semiconductor layer having arsenic or phosphorus, for example, as an n-type impurity, and a concentration of the n-type impurity is 1.0E+17/cm³ to 1.0E+20/cm³. The n⁺-type emitter layer 13 is provided to be alternating with a p⁺-type contact layer 14 along an extension direction of the active trench gate 11. The p⁺-type contact layer 14 is also provided between two the dummy trench gates 12 adjacent to each other. The p⁺-type contact layer 14 is a semiconductor layer having boron or aluminum, for example, as a p-type impurity, and a concentration of the p-type impurity is 1.0E+15/cm³ to 1.0E+20/cm³.

As illustrated in FIG. 5, three dummy trench gate 12 are arranged adjacent to three active trench gates 11, and three active trench gates 11 are arranged adjacent to three dummy trench gates 12 in the IGBT region 10 in the semiconductor device 101. In this manner, the IGBT region 10 has a configuration that a group of the active trench gates 11 and a group of the dummy trench gates 12 are alternately arranged. In FIG. 5, the number of the active trench gates 11 included in one group of active trench gates 11 is three, however, any number equal to or larger than 1 is applicable. The number of the dummy trench gates 12 included in one group of dummy trench gates 12 may be one or more, and the number of the dummy trench gates 12 may be zero. That is to say, all of the trenches provided to the IGBT region 10 may be the active trench gate 11.

FIG. 6 is a cross-sectional view at the broken line A-A in FIG. 5 of the semiconductor device 101, and is a cross-sectional view of the IGBT region 10. The semiconductor device 101 includes an n⁻-type drift layer 1 made up of a semiconductor substrate. The n⁻-type drift layer 1 is a semiconductor layer having arsenic or phosphorus, for example, as an n-type impurity, and a concentration of the n-type impurity is 1.0E+12/cm³ to 1.0E+15/cm³. The semiconductor substrate ranges from the n⁺-type emitter layer 13 and the p⁺-type contact layer 14 to the p-type collector layer 16 in FIG. 6. In FIG. 6, an upper end of the paper sheet of the n⁺-type emitter layer 13 and the p⁺-type contact layer 14 is a first main surface of the semiconductor substrate, and a lower end of the paper sheet of the p-type collector layer 16 is a second main surface of the semiconductor substrate. The first main surface of the semiconductor substrate is a main surface of the semiconductor device 101 on the front surface side, and the second main surface of the semiconductor substrate is a main surface of the semiconductor device 101 on a back surface side opposed to the first main surface. The semiconductor device 101 includes the n⁻-type drift layer 1 between the first main surface and the second main surface in the IGBT region 10.

As illustrated in FIG. 6, an n-type carrier accumulation layer 2 having a higher n-type impurity than the n⁻-type drift layer 1 is provided on a side of a first main surface of the n⁻-type drift layer 1. The n-type carrier accumulation layer 2 is a semiconductor layer having arsenic or phosphorus, for example, as an n-type impurity, and a concentration of the n-type impurity is 1.0E+13/cm³ to 1.0E+17/cm³. The semiconductor device 101 may have a configuration that the n-type carrier accumulation layer 2 is not provided, but the n⁻-type drift layer 1 is provided also in the region of the n-type carrier accumulation layer 2 illustrated in FIG. 6. The n-type carrier accumulation layer 2 is provided, thus power conduction loss at a time of flowing current in the IGBT region 10 can be reduced. The n-type carrier accumulation layer 2 and the n⁻-type drift layer 1 may be collectively referred to as a drift layer.

The n-type carrier accumulation layer 2 is formed by ion-implanting an n-type impurity into the semiconductor substrate constituting the n⁻-type drift layer 1 and subsequently diffusing the implanted n-type impurity into the semiconductor substrate as the n⁻-type drift layer 1 by annealing.

A p-type base layer 15 is provided on the side of the first main surface of the n-type carrier accumulation layer 2. The p-type base layer 15 is a semiconductor layer having boron or aluminum, for example, as a p-type impurity, and a concentration of the p-type impurity is 1.0E+12/cm³ to 1.0E+19/cm³. The p-type base layer 15 has contact with the gate trench insulating film 11b of the active trench gate 11. The n⁺-type emitter layer 13 is provided on a side of a first main surface of the p-type base layer 15 to have contact with the gate trench insulating film 11b of the active trench gate 11, and the p⁺-type contact layer 14 is provided to a remaining region. The n⁺-type emitter layer 13 and the p⁺-type contact layer 14 constitute the first main surface of the semiconductor substrate. The p⁺-type contact layer 14 is a region having a higher p-type impurity concentration than the p-type base layer 15. When the p⁺-type contact layer 14 and the p-type base layer 15 need to be distinguished, they may be individually referred, and the p⁺-type contact layer 14 and the p-type base layer 15 may be collectively referred to as the p-type base layer.

The n-type buffer layer 3 having a higher n-type impurity concentration than the n⁻-type drift layer 1 is provided on a side of the second main surface of the n⁻-type drift layer 1 in the semiconductor device 101. The n-type buffer layer 3 is provided to suppress punch-through of a depletion layer extending from the p-type base layer 15 to the side of the second main surface when the semiconductor device 101 is in an off state. The n-type buffer layer 3 may be formed by implanting phosphorus (P) or proton (H+), for example, or may also be formed by implanting both phosphorus (P) and proton (H+). The concentration of the n-type impurity of the n-type buffer layer 3 is 1.0E+12/cm³ to 1.0E+18/cm³. The semiconductor device 101 may have a configuration that the n-type buffer layer 3 is not provided, but the n⁻-type drift layer 1 is provided also in the region of the n-type buffer layer 3 illustrated in FIG. 6. The n-type buffer layer 3 and the n⁻-type drift layer 1 may be collectively referred to as a drift layer.

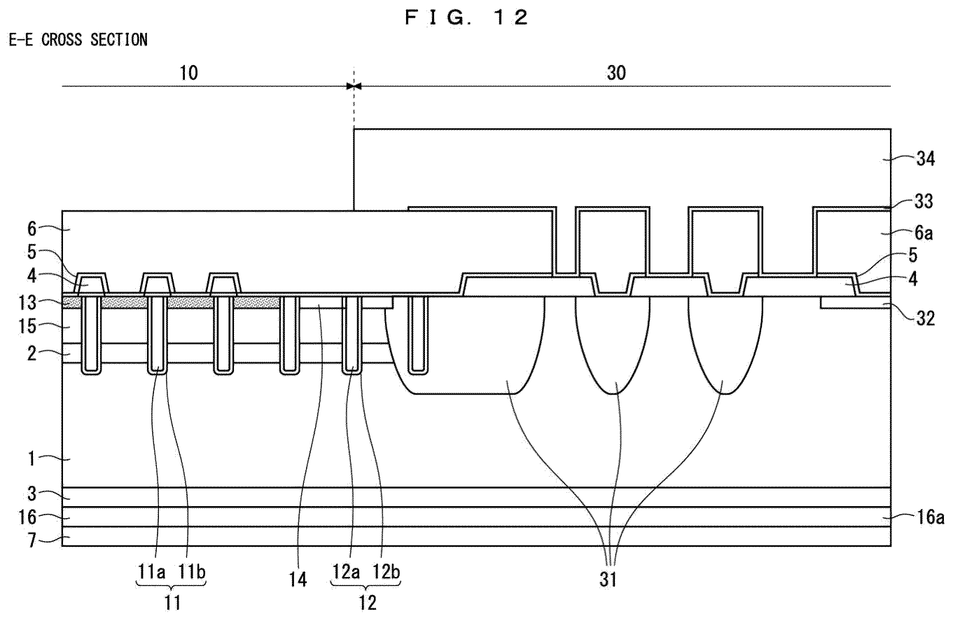

The p-type collector layer 16 is provided on a side of a second main surface of the n-type drift layer 3 in the semiconductor device 101. That is to say, the p-type collector layer 16 is provided between the n⁻-type drift layer 1 and the second main surface. The p-type collector layer 16 is a semiconductor layer having boron or aluminum, for example, as a p-type impurity, and a concentration of the p-type impurity is 1.0E+16/cm³ to 1.0E+20/cm³. The p-type collector layer 16 constitutes the second main surface of the semiconductor substrate. The p-type collector layer 16 is provided to not only the IGBT region 10 but also the terminal region 30, and a part of the p-type collector layer 16 provided to the terminal region 30 constitutes a p-type terminal collector layer 16a (refer to FIG. 12). The p-type collector layer 16 may be provided to partially protrude to the diode region 20 from the IGBT region 10.

As illustrated in FIG. 6, formed in the semiconductor device 101 is a trench passing through the p-type base layer 15 from the first main surface of the semiconductor substrate to reach the n⁻-type drift layer 1. The gate trench electrode 11a is provided in the trench via the gate trench insulating film 11b to constitute the active trench gate 11. The gate trench electrode 11a faces the n⁻-type drift layer 1 via the gate trench insulating film 11b. The gate trench insulating film 11b has contact with the p-type base layer 15 and the n⁺-type emitter layer 13. When gate drive voltage is applied to the gate trench electrode 11a, a channel is formed in the p-type base layer 15 having contact with the gate trench insulating film 11b of the active trench gate 11.

The dummy trench electrode 12a is provided in the trench via the dummy trench insulating film 12b to constitute the dummy trench gate 12. The dummy trench electrode 12a faces the n⁻-type drift layer 1 via the dummy trench insulating film 12b. The dummy trench insulating film 12b also has contact with the p-type base layer 15 and the n⁺-type emitter layer 13 in the manner similar to the gate trench insulating film 11b, however, emitter voltage is applied to the dummy trench electrode 12a, thus a channel is not formed in the p-type base layer 15 having contact with the dummy trench insulating film 12b of the dummy trench gate 12.

As illustrated in FIG. 6, an interlayer insulating film 4 is provided on the gate trench electrode 11a of the active trench gate 11. A barrier metal 5 is formed on a region where the interlayer insulating film 4 is not provided on the first main surface of the semiconductor substrate and on the interlayer insulating film 4. The barrier metal 5 may be a conductor including titanium (Ti), titanium nitride, or TiSi in which titanium and silicon (Si) are alloyed, for example. As illustrated in FIG. 6, the barrier metal 5 has ohmic-contact with the n⁺-type emitter layer 13, p⁺-type contact layer 14, and the dummy trench electrode 12a, and is electrically connected to the n⁺-type emitter layer 13, p⁺-type contact layer 14, and the dummy trench electrode 12a.

An emitter electrode 6 is provided on the barrier metal 5. The emitter electrode 6 may be formed of aluminum alloy such as aluminum silicon alloy (Al—Si series alloy), for example, or may also be an electrode made up of a metal film of a plurality of layers in which a plating film is formed by a non-electrolytic plating or an electrolytic plating on an electrode formed by aluminum alloy. The plating film formed by the non-electrolytic plating or the electrolytic plating may be a nickel (Ni) plating film, for example. When there is a region such as a minute region between the interlayer insulating films 4 adjacent to each other where favorable embedding cannot be obtained by the emitter electrode 6, tungsten having more favorable embedding properties than the emitter electrode 6 may be disposed in the minute region to provide the emitter electrode 6 on tungsten. It is also applicable that the barrier metal 5 is not provided but the emitter electrode 6 is provided on the n⁺-type emitter layer 13, the p⁺-type contact layer 14, and the dummy trench electrode 12a. The barrier metal 5 may be provided only on an n-type semiconductor layer such as the n⁺-type emitter layer 13. The barrier metal 5 and the emitter electrode 6 may be collectively referred to as the emitter electrode.

FIG. 6 illustrates a diagram in which the interlayer insulating film 4 is not provided on the dummy trench electrode 12a of the dummy trench gate 12, however, the interlayer insulating film 4 may also be formed on the dummy trench electrode 12a of the dummy trench gate 12. When the interlayer insulating film 4 is formed on the dummy trench electrode 12a of the dummy trench gate 12, it is sufficient that the emitter electrode 6 and the dummy trench electrode 12a are electrically connected to each other in the other cross section (not shown).

A collector electrode 7 is provided on a side of a second main surface of the p-type collector layer 16. The collector electrode 7 may be made of aluminum alloy or aluminum alloy and a plating film in the manner similar to the emitter electrode 6. The collector electrode 7 may have a configuration different from the emitter electrode 6. The collector electrode 7 has ohmic-contact with the p-type collector layer 16, and is electrically connected thereto.

FIG. 7 is a cross-sectional view at the broken line B-B in FIG. 5 of the semiconductor device 101, and is a cross-sectional view of the IGBT region 10. The cross-sectional view at the broken line B-B in FIG. 7 is different from the cross-sectional view at the broken line A-A in FIG. 6 in that the n⁺-type emitter layer 13 having contact with the active trench gate 11 and provided on the side of the first main surface of the semiconductor substrate is not shown in the cross section at the broken line B-B in FIG. 7. That is to say, as illustrated in FIG. 5, the n⁺-type emitter layer 13 is selectively provided on the side of the first main surface of the p-type base layer. The p-type base layer herein indicates the p-type base layer as which the p-type base layer 15 and the p⁺-type contact layer 14 are collectively referred to.

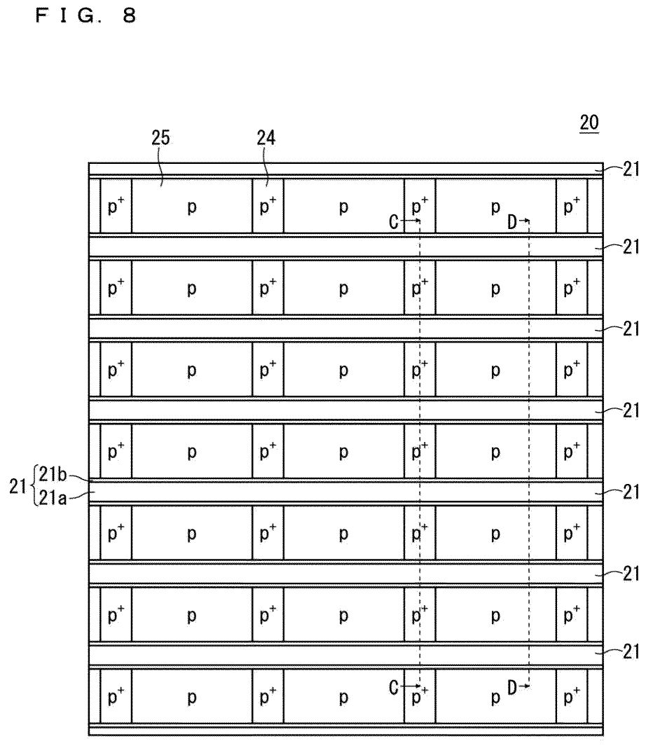

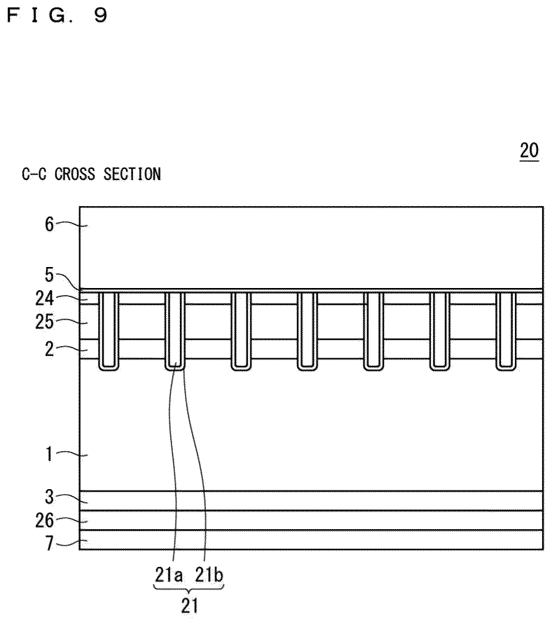

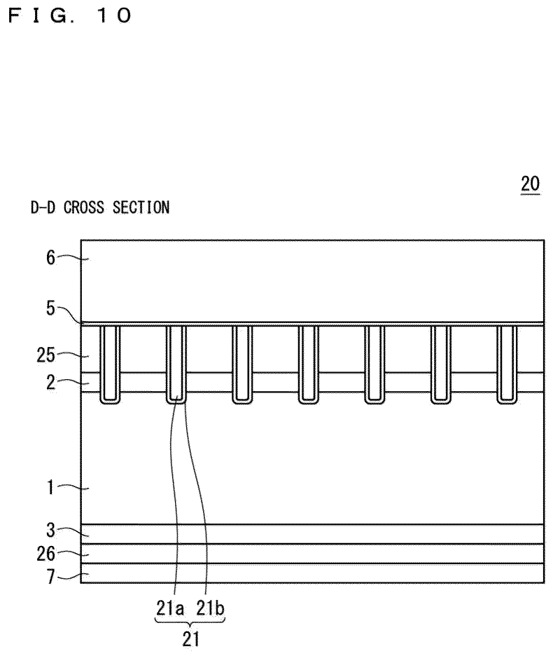

FIG. 8 is a partial enlarged plan view illustrating a configuration of the diode region in the semiconductor device as the RC-IGBT. FIG. 9 and FIG. 10 are cross-sectional views each illustrating a configuration of the diode region in the semiconductor device as the RC-IGBT. FIG. 8 illustrates an enlarged view of a region surrounded by a broken line 83 in the semiconductor device 101 illustrated in FIG. 1. FIG. 9 illustrates a cross-sectional view at a broken line C-C in the semiconductor device 101 illustrated in FIG. 8. FIG. 10 illustrates a cross-sectional view at a broken line D-D in the semiconductor device 101 illustrated in FIG. 8.

A diode trench gate 21 extends from one end side of the diode region 20 toward the other end side opposed to the one end side along the first main surface of the semiconductor device 101. The diode trench gate 21 is made by providing a diode trench electrode 21a in the trench formed in the semiconductor substrate in the diode region 20 via a diode trench insulating film 21b. The diode trench electrode 21a faces the n⁻-type drift layer 1 via the diode trench insulating film 21b. A p⁺-type contact layer 24 and a p-type anode layer 25 are provided between two diode trench gates 21 adjacent to each other. The p⁺-type contact layer 24 is a semiconductor layer having boron or aluminum, for example, as a p-type impurity, and a concentration of the p-type impurity is 1.0E+15/cm³ to 1.0E+20/cm³. The p-type anode layer 25 is a semiconductor layer having boron or aluminum, for example, as a p-type impurity, and a concentration of the p-type impurity is 1.0E+12/cm³ to 1.0E+19/cm³. The p⁺-type contact layer 24 and the p-type anode layer 25 are alternately provided in a longitudinal direction of the diode trench gate 21.

FIG. 9 is a cross-sectional view at the broken line C-C in FIG. 8 of the semiconductor device 101, and is a cross-sectional view of the diode region 20. The semiconductor device 101 includes the n⁻-type drift layer 1 made up of a semiconductor substrate in the manner similar to the IGBT region 10 also in the diode region 20. The n⁻-type drift layer 1 of the diode region 20 and the n⁻-type drift layer 1 of the IGBT region 10 are continuously and integrally formed, and are formed by the same semiconductor substrate. In FIG. 9, the semiconductor substrate ranges from the p⁺-type contact layer 24 to an n⁺-type cathode layer 26. In FIG. 9, an upper end of a paper sheet of the p⁺-type contact layer 24 is referred to as the first main surface of the semiconductor substrate, and a lower end of a paper sheet of the n⁺-type cathode layer 26 is referred to as the second main surface of the semiconductor substrate. A first main surface of the diode region 20 and a first main surface of the IGBT region 10 are the same surface, and a second main surface of the diode region 20 and a second main surface of the IGBT region 10 are the same surface.

As illustrated in FIG. 9, the n-type carrier accumulation layer 2 is provided on the side of the first main surface of the n⁻-type drift layer 1, and the n-type buffer layer 3 is provided on the side of the second main surface of the n⁻-type drift layer 1 in the manner similar to the IGBT region 10 also in the diode region 20. The n-type carrier accumulation layer 2 and the n-type buffer layer 3 provided to the diode region 20 have the same configuration as the n-type carrier accumulation layer 2 and the n-type buffer layer 3 provided to the IGBT region 10. The n-type carrier accumulation layer 2 needs not be necessarily provided to the IGBT region 10 and the diode region 20, however, also applicable is a configuration that the n-type carrier accumulation layer 2 is not provided to the diode region 20 even when the n-type carrier accumulation layer 2 is provided to the IGBT region 10. The n⁻-type drift layer 1, the n-type carrier accumulation layer 2, and the n-type buffer layer 3 may be collectively referred to as the drift layer in the manner similar to the IGBT region 10.

The p-type anode layer 25 is provided on the side of the first main surface of the n-type carrier accumulation layer 2. The p-type anode layer 25 is provided between the n⁻-type drift layer 1 and the first main surface. The p-type anode layer 25 and the p-type base layer 15 may be formed at the same time by making the p-type anode layer 25 have the same concentration of the p-type impurity as the p-type base layer 15 of the IGBT region 10. Also applicable is a configuration that a concentration of a p-type impurity of the p-type anode layer 25 is lower than that of the p-type base layer 15 to reduce an amount of holes implanted into the diode region 20 in a diode operation. The amount of holes implanted into the diode operation is reduced, thus recovery loss in the diode operation can be reduced.

The p⁺-type contact layer 24 is provided on the side of the first main surface of the p-type anode layer 25. The concentration of the p-type impurity of the p⁺-type contact layer 24 may be the same as or different from that of the p⁺-type contact layer 14 of the IGBT region 10. The p⁺-type contact layer 24 constitutes the first main surface of the semiconductor substrate. The p⁺-type contact layer 24 is a region having a higher p-type impurity concentration than the p-type anode layer 25. When the p⁺-type contact layer 24 and the p-type anode layer 25 need to be distinguished, they may be individually referred, and the p⁺-type contact layer 24 and the p-type anode layer 25 may be collectively referred to as the p-type anode layer.

The n⁺-type cathode layer 26 is provided on the side of the second main surface of the n-type buffer layer 3 in the diode region 20. The n⁺-type cathode layer 26 is provided between the n⁻-type drift layer 1 and the second main surface. The n⁺-type cathode layer 26 is a semiconductor layer having arsenic or phosphorus, for example, as an n-type impurity, and a concentration of the n-type impurity is 1.0E+16/cm³ to 1.0E+21/cm³. The n⁺-type cathode layer 26 is partially or wholly provided to the diode region 20. The n⁺-type cathode layer 26 constitutes the second main surface of the semiconductor substrate. Although not shown in the diagrams, it is also applicable that the p-type impurity is further selectively implanted into the region where the n⁺-type cathode layer 26 is formed as described above and the p-type cathode layer as the p-type semiconductor is provided to a part of the region where the n⁺-type cathode layer 26 is formed.

As illustrated in FIG. 9, formed in the diode region 20 in the semiconductor device 101 is a trench passing through the p-type anode layer 25 from the first main surface of the semiconductor substrate to reach the n⁻-type drift layer 1. A diode trench electrode 21a is provided in the trench in the diode region 20 via the diode trench insulating film 21b, thus the diode trench gate 21 is formed. The diode trench electrode 21a faces the n⁻-type drift layer 1 via the diode trench insulating film 21b.

As illustrated in FIG. 9, the barrier metal 5 is provided on the diode trench electrode 21a and the p⁺-type contact layer 24. The barrier metal 5 has ohmic-contact with the diode trench electrode 21a and the p⁺-type contact layer 24, and is electrically connected to the diode trench electrode and the p⁺-type contact layer 24. The barrier metal 5 may have the same configuration as the barrier metal 5 in the IGBT region 10. The emitter electrode 6 is provided on the barrier metal 5. The emitter region 6 provided to the diode region 20 is formed continuously with the emitter electrode 6 provided to the IGBT region 10. In the manner similar to the case of the IGBT region 10, it is also applicable that the barrier metal 5 is not provided but the diode trench electrode 21a and the p⁺-type contact layer 24 have ohmic-contact with the emitter electrode 6. FIG. 9 illustrates a diagram in which the interlayer insulating film 4 is not provided on the diode trench electrode 21a of the diode trench gate 21, however, the interlayer insulating film 4 may be formed on the diode trench electrode 21a of the diode trench gate 21. When the interlayer insulating film 4 is formed on the diode trench electrode 21a of the diode trench gate 21, it is sufficient that the emitter electrode 6 and the diode trench electrode 21a are electrically connected to each other in the other cross section (not shown).

The collector electrode 7 is provided on a side of a second main surface of the n⁺-type cathode layer 26. The collector electrode 7 in the diode region 20 is formed continuously with the collector electrode 7 provided to the IGBT region 10 in the manner similar to the emitter electrode 6. The collector electrode 7 has ohmic-contact with the n⁺-type cathode layer 26, and is electrically connected thereto.

FIG. 10 is a cross-sectional view at a broken line D-D in FIG. 8 of the semiconductor device 101, and is a cross-sectional view of the diode region 20. The cross-sectional view at the broken line D-D in FIG. 10 is different from the cross-sectional view at the broken line C-C in FIG. 9 in that the p⁺-type contact layer 24 is not provided between the p-type anode layer 25 and the barrier metal 5, and the p-type anode layer 25 constitutes the first main surface of the semiconductor substrate. That is to say, the p⁺-type contact layer 24 illustrated in FIG. 9 is selectively provided on the side of the first main surface of the p-type anode layer 25.

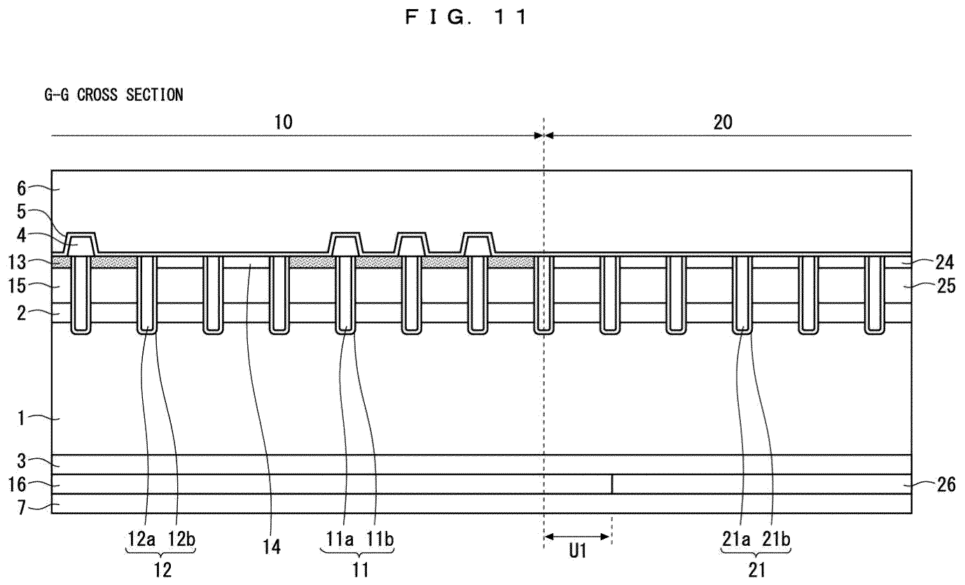

FIG. 11 is a cross-sectional view illustrating a configuration of a boundary between the IGBT region and the diode region in the semiconductor device as the RC-IGBT. FIG. 11 illustrates a cross-sectional view at a broken line G-G in the semiconductor device 101 illustrated in FIG. 1.

As illustrated in FIG. 11, the p-type collector layer 16 provided on the side of the second main surface of the IGBT region 10 is provided to protrude to a side of diode region 20 by a distance U1 from the boundary between the IGBT region 10 and the diode region 20. In this manner, the p-type collector layer 16 is provided to protrude to diode region 20, thus a distance from the n⁺-type cathode layer 26 in the diode region 20 to the active trench gate 11 can be increased, thus when gate drive voltage is applied to the gate trench electrode 11a in a reflux diode operation, current flowing to the n⁺-type cathode layer 26 from a channel formed adjacent to the active trench gate 11 in the IGBT region 10 can be suppressed. The distance U1 may be 100 μm, for example. The distance U1 may be zero or smaller than 100 μm depending on an intended use of the semiconductor device 101 as the RC-IGBT.

FIG. 12 is a cross-sectional view illustrating a configuration of the terminal region in the semiconductor device as the RC-IGBT. FIG. 12 is a cross-sectional view at a broken line E-E in FIG. 1, and is a cross-sectional view from the IGBT region 10 to the terminal region 30. Illustration of the gate wiring region 50 is omitted in FIG. 12.

As illustrated in FIG. 12, the terminal region 30 in the semiconductor device 101 includes the n⁻-type drift layer 1 between the first main surface and the second main surface of the semiconductor substrate. A first main surface and a second main surface of the terminal region 30 are the same surfaces as the first main surface and the second main surface of the IGBT region 10 and diode region 20, respectively. The n⁻-type drift layer 1 in the terminal region 30 has the same configuration as the n⁻-type drift layer 1 in the IGBT region 10 and diode region 20, and is continuously and integrally formed.

A p-type terminal well layer 31 is provided on the side of the first main surface of the n⁻-type drift layer 1, that is to say, between the first main surface of the semiconductor substrate and the n⁻-type drift layer 1. The p-type terminal well layer 31 is a semiconductor layer having boron or aluminum, for example, as a p-type impurity, and a concentration of the p-type impurity is 1.0E+14/cm³ to 1.0E+19/cm³. The p-type terminal well layer 31 is provided to surround a cell region including the IGBT region 10 and the diode region 20. The plurality of p-type terminal well layers 31 are provided to each have a ring-like shape, and the number of the p-type terminal well layers 31 is appropriately selected by a withstand voltage design of the semiconductor device 101. An n⁺-type channel stopper layer 32 is provided to a further outer edge side of the p-type terminal well layer 31, and the n⁺-type channel stopper layer 32 surrounds the p-type terminal well layer 31.

The p-type terminal collector layer 16a is provided between the n⁻-type drift layer 1 and the second main surface of the semiconductor substrate. The p-type terminal collector layer 16a is continuously and integrally formed with the p-type collector layer 16 provided to the cell region. Accordingly, the p-type terminal collector layer 16a may be collectively referred to as the p-type collector layer 16.

The collector electrode 7 is provided on the second main surface of the semiconductor substrate. The collector electrode 7 is continuously and integrally formed from the cell region including the IGBT region 10 and the diode region 20 to the terminal region 30. In the meanwhile, the emitter electrode 6 continuously formed from the cell region and the terminal electrode 6a separated from the emitter electrode 6 are provided on the first main surface of the semiconductor substrate in the terminal region 30.

The emitter electrode 6 and the terminal electrode 6a are electrically connected via a semi-insulating film 33. The semi-insulating film 33 may be a semi-insulating silicon nitride (sinSiN) film, for example. The terminal electrode 6a is electrically connected to the p-type terminal well layer 31 and the n⁺-type channel stopper layer 32 via a contact hole formed in the interlayer insulating film 4 provided on the first main surface of the terminal region 30. A terminal protection film 34 is provided to cover the emitter electrode 6, the terminal electrode 6a, and the semi-insulating film 33 in the terminal region 30. The terminal protection film 34 is formed of polyimide, for example.

Described hereinafter is an example of a method of manufacturing the semiconductor device as the RC-IGBT according to the embodiment 1.

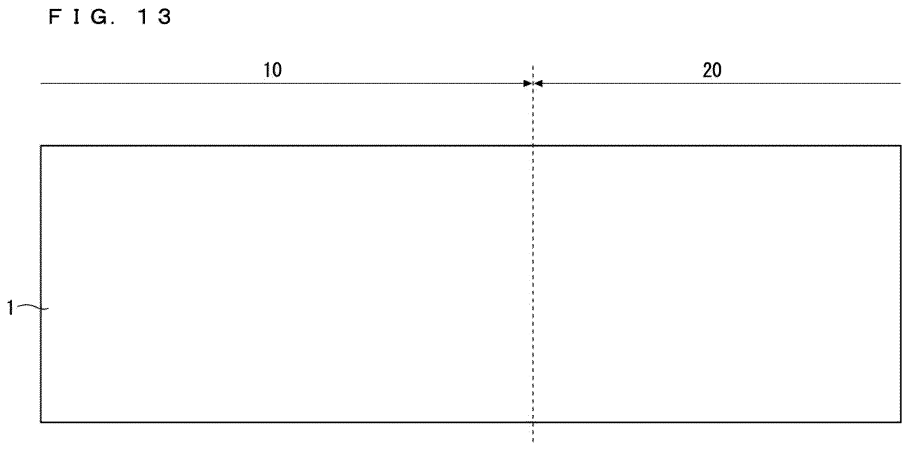

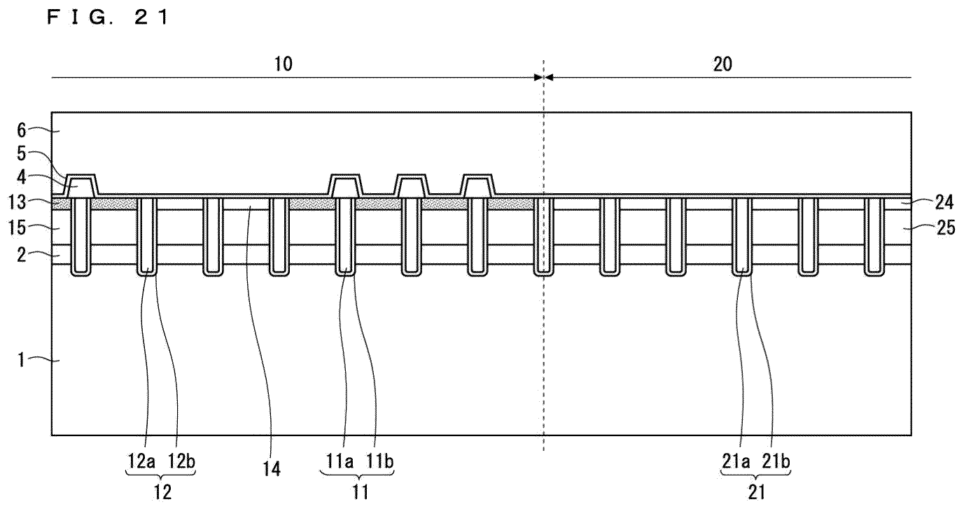

FIG. 13 to FIG. 24 are diagrams each illustrating a method of manufacturing the semiconductor device 101 as the RC-IGBT. FIG. 13 to FIG. 20 are diagrams each illustrating a process of forming the front surface side of the semiconductor device 101, and FIG. 21 to FIG. 24 are diagrams each illustrating a process of forming the back surface side of the semiconductor device 101.

Firstly, a semiconductor substrate constituting the n⁻-type drift layer 1 is prepared as illustrated in FIG. 13. A so-called floating zone (FZ) wafer manufactured by an FZ method or a magnetic applied Czochralski (MCZ) wafer manufactured by an MCZ method may be used for the semiconductor substrate, and an n-type wafer including an n-type impurity is applicable. A concentration of the n-type impurity included in the semiconductor substrate is appropriately selected by withstand voltage of the manufactured semiconductor device. For example, in a semiconductor device having withstand voltage of 1200 V, the concentration of the n-type impurity is adjusted so that specific resistance of the n⁻-type drift layer 1 constituting the semiconductor substrate is substantially 40 to 120 Ω·cm. As illustrated in FIG. 13, the whole semiconductor substrate is the n⁻-type drift layer 1 in the process of preparing the semiconductor substrate. P-type or n-type impurity ions are implanted from the side of the first main surface or the second main surface of such a semiconductor substrate, and are subsequently diffused in the semiconductor substrate by thermal processing, for example, thereby forming a p-type or n-type semiconductor layer, thus the semiconductor device 101 is manufactured.

As illustrated in FIG. 13, the semiconductor substrate constituting the n⁻-type drift layer 1 includes a region serving as the IGBT region 10 and the diode region 20. Although not shown in FIG. 13, the semiconductor substrate includes a region serving as the terminal region 30 around the region serving as the IGBT region 10 and the diode region 20. Described mainly hereinafter is a method of manufacturing a configuration of the IGBT region 10 and the diode region 20 in the semiconductor device 101. The terminal region 30 in the semiconductor device 101 may be manufactured by a known manufacturing method. For example, when an FLR including the p-type terminal well layer 31 is formed as a withstand voltage holding structure in the terminal region 30, the p-type impurity ion may be implanted before the IGBT region 10 and the diode region 20 are processed in the semiconductor device 101, or the p-type impurity ion may be implanted at the same time as the ion-implantation of the p-type impurity in the IGBT region 10 or the diode region 20 in the semiconductor device 101.

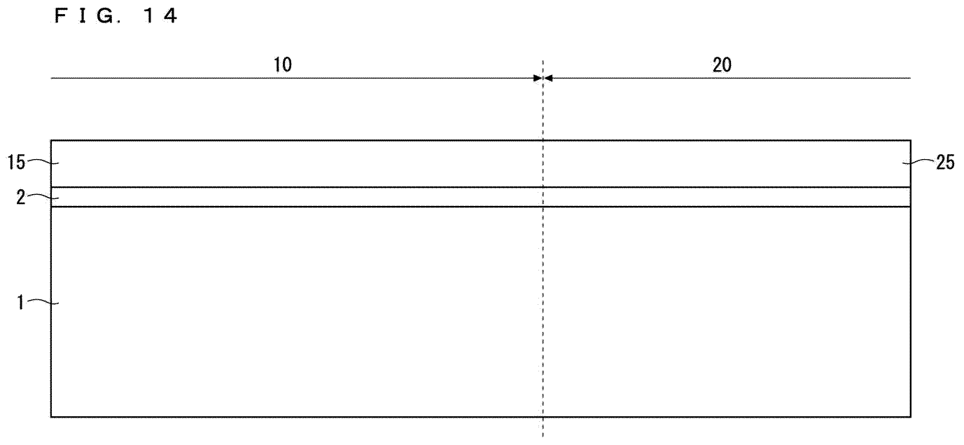

Next, as illustrated in FIG. 14, the n-type impurity such as phosphorus (P) is implanted from the side of the first main surface of the semiconductor substrate to form the n-type carrier accumulation layer 2. The p-type impurity such as boron (B) is implanted from the side of the first main surface of the semiconductor substrate to form the p-type base layer 15 and the p-type anode layer 25. The n-type carrier accumulation layer 2, the p-type base layer 15, and the p-type anode layer 25 are formed by diffusing the impurity ions by the thermal processing after implanting the impurity ions into the semiconductor substrate. The n-type impurity and the p-type impurity are ion-implanted after the mask processing is performed on the first main surface of the semiconductor substrate, thus are selectively formed on the side of the first main surface of the semiconductor substrate. The n-type carrier accumulation layer 2, the p-type base layer 15, and the p-type anode layer 25 are formed in the IGBT region 10 and the diode region 20, and are connected to the p-type terminal well layer 31 in the terminal region 30. The mask processing indicates processing of forming a mask on the semiconductor substrate for applying a resist on the semiconductor substrate, forming an opening in a predetermined region in the resist using a photomechanical technique, implanting ions into a predetermined region in the semiconductor substrate via the opening, and performing etching.

The p-type base layer 15 and the p-type anode layer 25 may be formed by ion-implanting the p-type impurity at the same time. In this case, the p-type base layer 15 and the p-type anode layer 25 have the same depth and p-type impurity concentration, thus have the same configuration. It is applicable that the p-type impurity is separately ion-implanted into the p-type base layer 15 and the p-type anode layer 25 by the mask processing to make the depth and the p-type impurity concentration of the p-type base layer 15 and the p-type anode layer 25 different from each other.

The p-type terminal well layer 31 formed in the other cross section may be formed by ion-implanting the p-type impurity at the same time as the p-type anode layer 25. In this case, the p-type terminal well layer 31 and the p-type anode layer 25 have the same depth and p-type impurity concentration, thus can have the same configuration. It is also possible that the p-type impurity is ion-implanted into the p-type terminal well layer 31 and the p-type anode layer 25 at the same time to make the p-type impurity concentration of the p-type terminal well layer 31 and the p-type anode layer 25 different from each other. In this case, it is sufficient that an opening ratio is changed by making a mask of any one or both of them have a mesh-like shape.

It is applicable that the p-type impurity is separately ion-implanted into the p-type terminal well layer 31 and the p-type anode layer 25 by the mask processing to make the depth and the p-type impurity concentration of the p-type terminal well layer 31 and the p-type anode layer 25 different from each other.

The p-type terminal well layer 31, the p-type base layer 15, and the p-type anode layer 25 may be formed by ion-implanting the p-type impurity at the same time.

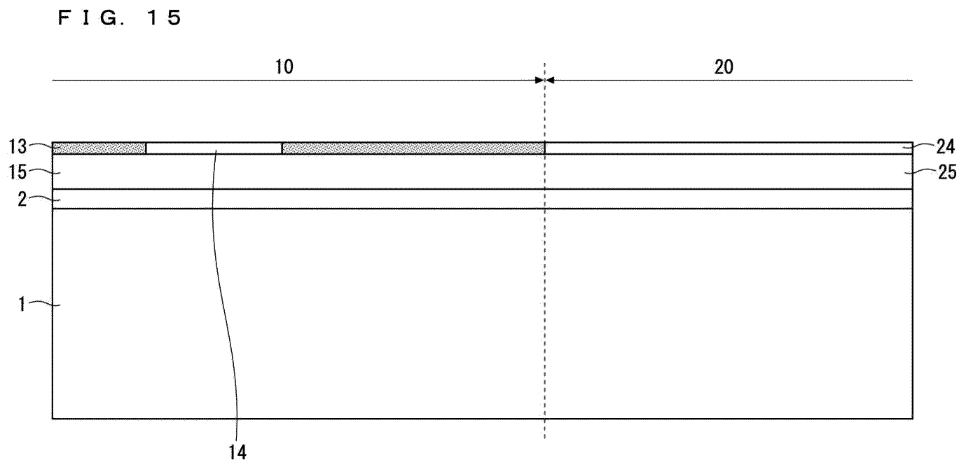

Next, as illustrated in FIG. 15, the n-type impurity is selectively implanted to the side of the first main surface of the p-type base layer 15 of the IGBT region 10 by the mask processing to form the n⁺-type emitter layer 13. The implanted n-type impurity may be arsenic (As) or phosphorus (P). The p-type impurity is selectively implanted to the side of the first main surface of the p-type base layer 15 of the IGBT region 10 by the mask processing, and the p-type impurity is selectively implanted to the side of the first main surface of the p-type anode layer 25 of the diode region 20 to form the p⁺-type contact layer 24. The implanted p-type impurity may be boron (B) or aluminum (Al), for example.

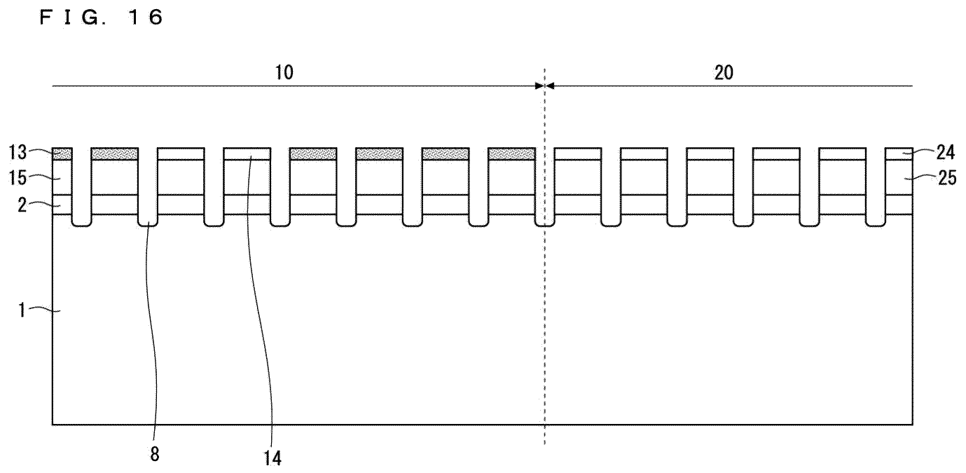

Next, as illustrated in FIG. 16. formed is a trench 8 passing through the p-type base layer 15 and the p-type anode layer 25 from the side of the first main surface of the semiconductor substrate to reach the n⁻-type drift layer 1. In the IGBT region 10, the trench 8 passing through the n⁺-type emitter layer 13 includes a sidewall constituting a part of the n⁺-type emitter layer 13. The trench 8 may be formed by depositing an oxide film of SiO₂, for example, on the semiconductor substrate, then forming an opening in the oxide film in a part where the trench 8 is formed by the mask processing, and etching the semiconductor substrate using the oxide film in which the opening is formed as a mask. In FIG. 16, a pitch of the trench 8 is the same as each other between the IGBT region 10 and the diode region 20, however, the pitch of the trench 8 may be different therebetween. The pitch of the trench 8 can be appropriately changed by a mask pattern in the mask processing.

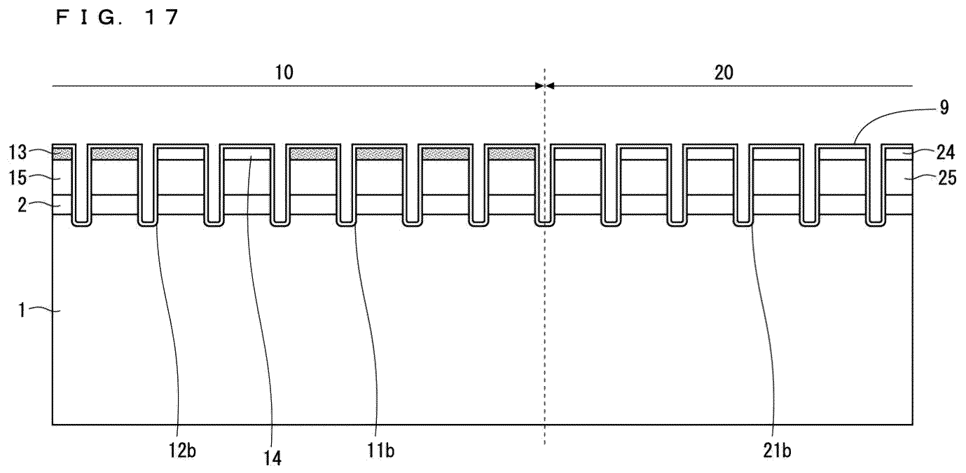

Next, as illustrated in FIG. 17, the semiconductor substrate is heated in an atmosphere including oxygen to form an oxide film 9 on an inner wall of the trench 8 and the first main surface of the semiconductor substrate. The oxide film 9 formed on the trench 8 of the IGBT region 10 in the oxide film 9 formed on the inner wall of the trench 8 is the gate trench insulating film 11b of the active trench gate 11 and the dummy trench insulating film 12b of the dummy trench gate 12. The oxide film 9 formed on the trench 8 of the diode region 20 is the diode trench insulating film 21b. The oxide film 9 formed on the first main surface of the semiconductor substrate 1 is removed in a subsequent process.

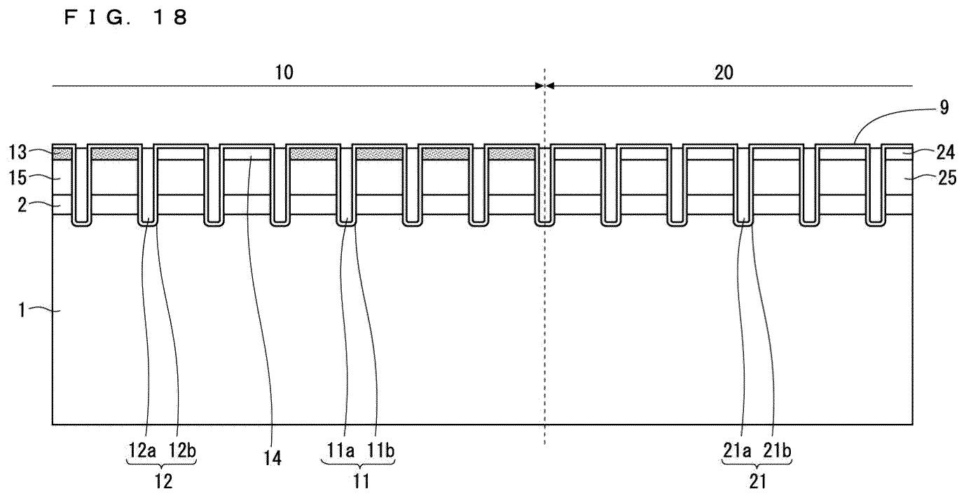

Next, as illustrated in FIG. 18, polysilicon doped with an n-type or p-type impurity by chemical vapor deposition (CVD), for example, is deposited in the trench 8 in which the oxide film 9 is formed on the inner wall to form the gate trench electrode 11a, the dummy trench electrode 12a, and the diode trench electrode 21a.

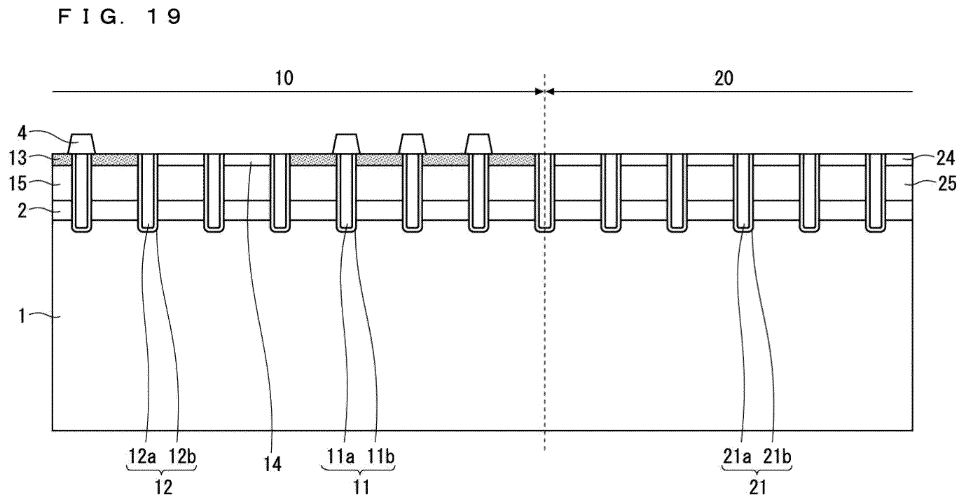

Next, as illustrated in FIG. 19, the interlayer insulating film 4 is formed on the gate trench electrode 11a of the active trench gate 11 in the IGBT region 10, and then the oxide film 9 formed on the first main surface of the semiconductor substrate is removed. The interlayer insulating film 4 may be SiO₂, for example. Then, the contact hole is formed in the interlayer insulating film 4 disposed by the mask processing. The contact hole is formed on the n⁺-type emitter layer 13, the p⁺-type contact layer 14, the p⁺-type contact layer 24, the dummy trench electrode 12a, and the diode trench electrode 21a.

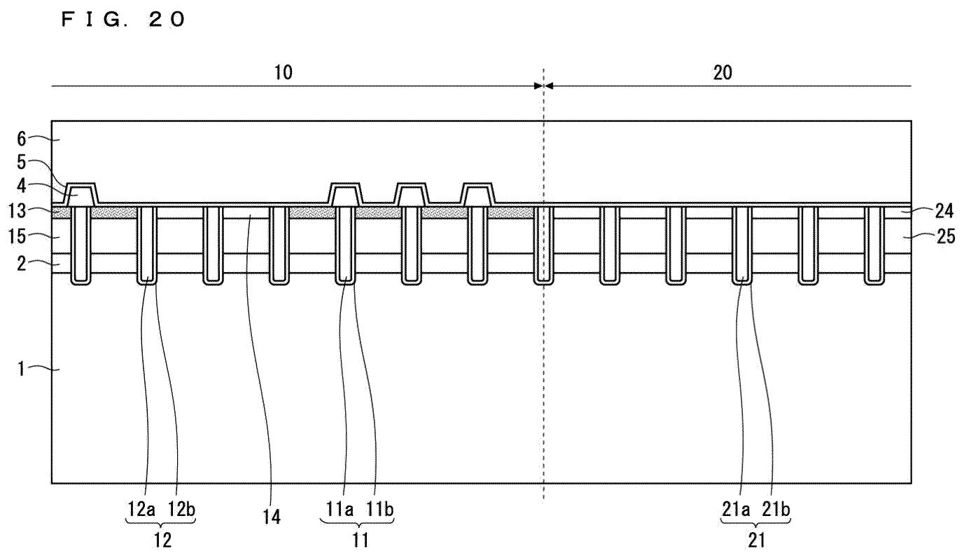

Next, as illustrated in FIG. 20, the barrier metal 5 is formed on the first main surface of the semiconductor substrate and the interlayer insulating film 4, and moreover, the emitter electrode 6 is formed on the barrier metal 5. The barrier metal 5 is formed by forming a film of titanium nitride by physical vapor deposition (PDV) or CVD.

The emitter electrode 6 may be formed by depositing aluminum silicon alloy (Al—Si series alloy) on the barrier metal 5 by PVD such as sputtering or vapor deposition. Nickel alloy (Ni alloy) may be further formed as the emitter electrode 6 by a non-electrolytic plating or an electrolytic plating on the formed aluminum silicon alloy. When the emitter electrode 6 is formed by plating, a thick metal film can be easily formed as the emitter electrode 6, thus heat capacity of the emitter electrode 6 can be increased to improve heat resistance. When nickel alloy is further formed by the plating processing after the emitter electrode 6 made of aluminum silicon alloy is formed by the PVD, the plating processing for forming the nickel alloy may be performed after performing processing on the side of the second main surface of the semiconductor substrate.

Next, as illustrated in FIG. 21, the side of the second main surface of the semiconductor substrate is ground to reduce the thickness of the semiconductor substrate to a predetermined designed thickness. The thickness of the semiconductor substrate after grinding may be 80 μm to 200 μm, for example.

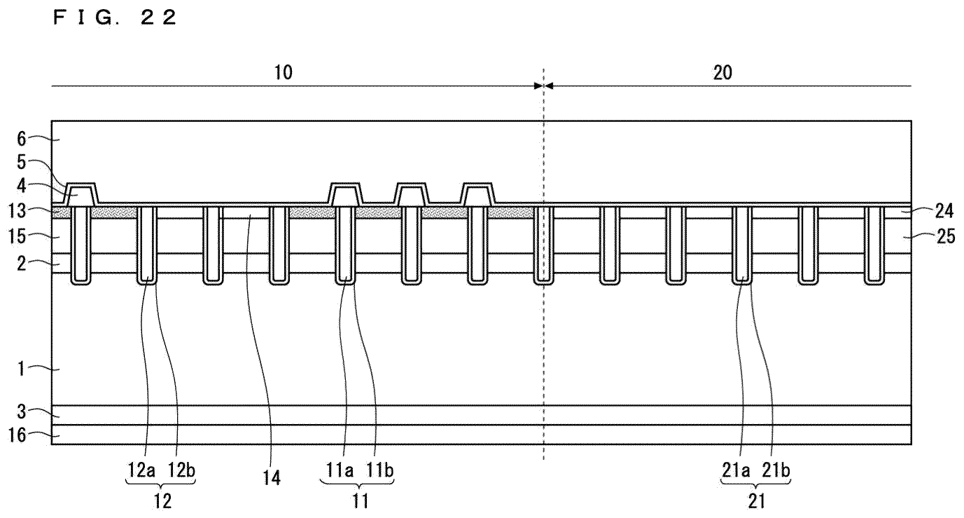

Next, as illustrated in FIG. 22, the n-type impurity is implanted from the side of the second main surface of the semiconductor substrate to form the n-type buffer layer 3. Furthermore, the p-type impurity is implanted from the side of the second main surface of the semiconductor substrate to form the p-type collector layer 16. The n-type buffer layer 3 may be formed in the IGBT region 10, the diode region 20, and the terminal region 30, or may also be formed only in the IGBT region 10 or the diode region 20.

The n-type buffer layer 3 may be formed by implanting phosphorus (P) ions, for example. The n-type buffer layer 3 may be formed by implanting proton (H+). The n-type buffer layer 3 may be formed by implanting both proton and phosphorus. Proton can be implanted from the second main surface of the semiconductor substrate to a deep position at relatively low acceleration energy. A depth of implanting proton can be changed relatively easily by changing the acceleration energy. Thus, when proton is implanted several times while changing the acceleration energy when the n-type buffer layer 3 is formed by proton, the n-type buffer layer 3 with a large width in a thickness direction of the semiconductor substrate compared with a case of forming the n-type buffer layer 3 by phosphorus can be formed.

An activation rate as the n-type impurity can be increased by phosphorus compared with proton, thus punch-through of a depletion layer can be suppressed more reliably even in a semiconductor substrate having a thin plate-like shape by forming the n-type buffer layer 3 by phosphorus. It is preferable that both proton and phosphorus are implanted to form the n-type buffer layer 3 to further reduce the thickness of the semiconductor substrate having the thin plate-like shape, and at this time, proton is implanted from the second main surface to a deeper position than phosphorus.

The p-type collector layer 16 may be formed by implanting boron (B), for example. The p-type collector layer 16 is formed also in the terminal region 30, and the p-type collector layer 16 in the terminal region 30 serves as the p-type terminal collector layer 16a. The second main surface is irradiated with laser to perform laser annealing after ions are implanted from the side of the second main surface of the semiconductor substrate, thus the implanted boron is activated to form the p-type collector layer 16. At this time, phosphorus for the n-type buffer layer 3 implanted from the second main surface of the semiconductor substrate to a relatively shallow position is also activated at the same time. In the meanwhile, proton is activated at a relatively low anneal temperature of 350° C. to 500° C., for example, thus needed is attention so that a temperature of the whole semiconductor substrate is not higher than 350° C. to 500° C. Laser annealing can make only an area near the second main surface of the semiconductor substrate have a high temperature, thus can be used for activating the n-type impurity or the p-type impurity even after implanting proton.

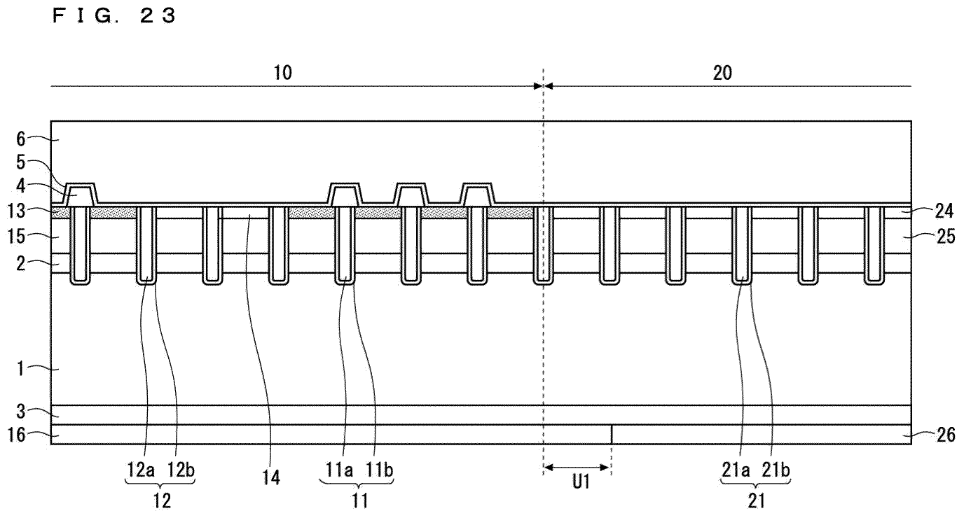

Next, as illustrated in FIG. 23, the n⁺-type cathode layer 26 is formed in the diode region 20. The n⁺-type cathode layer 26 may be formed by implanting phosphorus (P), for example. As illustrated in FIG. 23, phosphorus is selectively implanted from the side of the second main surface by the mask processing so that a boundary between the p-type collector layer 16 and the n⁺-type cathode layer 26 is located in a position on a side of the diode region 20 with the distance U1 from a boundary between the IGBT region 10 and the diode region 20. An amount of implantation of the n-type impurity for forming the n⁺-type cathode layer 26 is larger than that of implantation of the p-type impurity for forming the p-type collector layer 16. FIG. 23 illustrates that the p-type collector layer 16 and the n⁺-type cathode layer 26 have the same depth from the second main surface, however, the depth of the n⁺-type cathode layer 26 is equal to or larger than the p-type collector layer 16. The region where the n⁺-type cathode layer 26 is formed needs to be the n-type semiconductor by implanting the n-type impurity into the region where the p-type impurity is implanted, thus a concentration of the implanted p-type impurity in the whole region where the n⁺-type cathode layer 26 is formed is made to be higher than that of the n-type impurity.

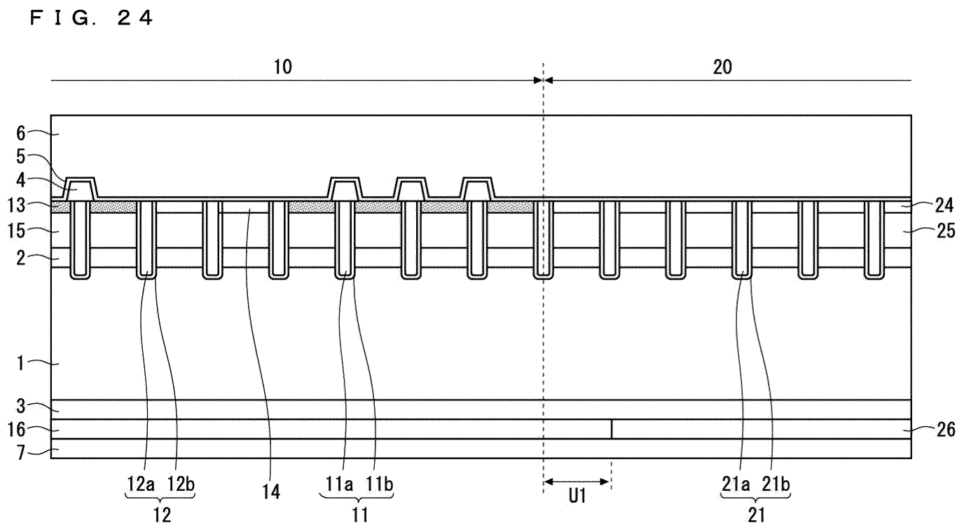

Next, as illustrated in FIG. 24, the collector electrode 7 is formed on the second main surface of the semiconductor substrate. The collector electrode 7 is formed over the whole IGBT region 10, diode region 20, and terminal region 30 in the second main surface. The collector electrode 7 may be formed over the whole second main surface of the n-type wafer as the semiconductor substrate. The collector electrode 7 may be formed by depositing aluminum silicon alloy (Al—Si series alloy) or titanium (Ti) by PVD such as sputtering or vapor deposition, or may also be formed by stacking plural types of metal such as aluminum silicon alloy, titanium, nickel, or gold, for example. Furthermore, a metal film may be further formed as the collector electrode 7 by a non-electrolytic plating or an electrolytic plating on the metal film formed by PVD.

The semiconductor device 101 is manufactured by the processes described above. The plurality of semiconductor devices 101 are manufactured in a matrix in one n-type wafer, thus the n-type wafer is divided into each the semiconductor device 101 by laser dicing or blade to achieve the semiconductor device 101.

### Modification Example 1

In a conventional semiconductor device, a temperature sensing diode needs to be disposed in a center of a chip where a temperature gets relatively high to measure more accurate Tj. FIG. 1 illustrates the example that the temperature sensing diode 100 is disposed in a center of a chip, however, a temperature of a whole chip is uniformized in the semiconductor device 101 according to the embodiment 1, thus accurate Tj can be measured even when the temperature sensing diode 100 is not disposed in the center of the chip. Thus, a degree of freedom is improved in the arrangement of the temperature sensing diode 100.

In the semiconductor device 101 according to the embodiment 1, the temperature sensing diode 100 may be disposed on an outer side of the effective region (that is to say, a region which is not sandwiched between the effective regions) in a plan view. For example, when the temperature sensing diode 100 is disposed near the temperature sensing diode pads 41d and 41e, a wiring connecting the temperature sensing diode 100 and the temperature sensing diode pads 41d and 41e can be can be shortened, and there is no need for a region for leading the wiring. Thus, reduced is a region used for leading the wiring connecting the temperature sensing diode 100 and the temperature sensing diode pads 41d and 41e (in the example in FIG. 1, the gate wiring region 50 in a part along a center line of the cell region), and an area of the effective region (effective area) can be increased. Increase in the area of the effective region contributes to uniformity of a chip temperature.

### Modification Example 2

A plating film (not shown) may be formed on the emitter electrode 6 as a metal layer disposed on an upper side of the effective region. That is to say, the emitter electrode 6 may be a laminated metal layer including a metal layer and a plating layer. Heat transmission and heat capacity caused by the plating film are added to the emitter electrode 6, and the temperature (Tj) of the topmost surface of the chip can be uniformized more effectively. A material mainly containing nickel can be used as the plating film. When a material mainly containing copper having higher heat conductivity is used as the plating film, a higher effect is obtained.

### Embodiment 2

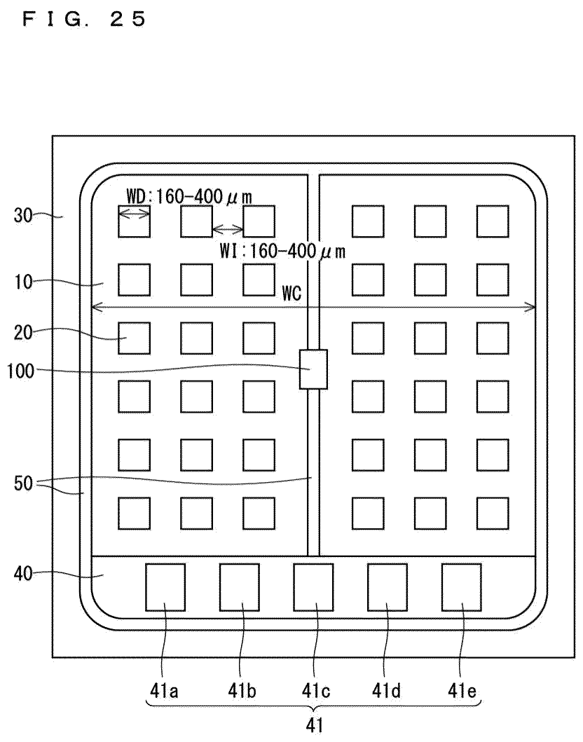

FIG. 25 is a plan view of a semiconductor device according to an embodiment 2. The semiconductor device according to the embodiment 2 is the same as the semiconductor device according to the embodiment 1 except that both WD (a length of one side of the diode region 20) and WI (an interval between the adjacent diode regions 20) range from 160 μm to 400 μm. When both WD and WI range from 160 μm to 400 μm, the effect described in the embodiment 1 is obtained more effectively.

### Embodiment 3

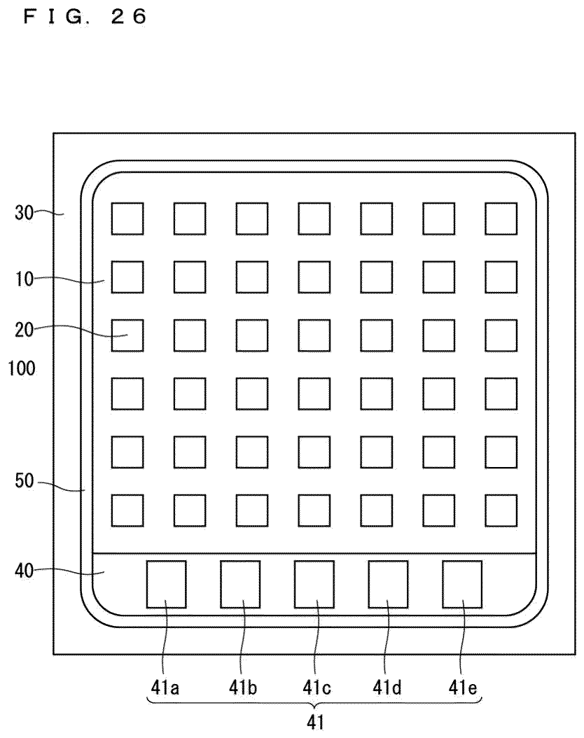

FIG. 26 is a plan view of a semiconductor device according to an embodiment 3. In the semiconductor device according to the embodiment 3, the gate wiring region 50 is provided to only an outer surrounding part of the effective region, and is not provided in the effective region. The other configuration thereof is similar to that of the embodiment 1.

In the semiconductor device 101 according to the embodiment 3, the area of the effective region increases compared with the embodiment 1, thus the division number of diode regions 20 can be increased, and the effect of reducing the temperature (Tj) of the topmost surface of the chip can be improved.

As described in the embodiment 1, the temperature sensing diode 100 (not shown in FIG. 26) needs not be disposed in the center of the chip in the semiconductor device 101 according to the technique of the present disclosure. Thus, achievable is a layout in FIG. 26 that the gate wiring region 50 for leading the wiring connecting the temperature sensing diode 100 and the temperature sensing diode pads 41d and 41e is not provided in the effective region.

In the configuration in FIG. 26, the emitter electrode 6 disposed on the effective region needs not be divided. A metal film for connecting a solder, for example, on the emitter electrode 6 is provided, and a lead frame, for example, is connected thereon in manufacturing a general semiconductor device. In an integral structure in which the emitter electrode 6 is not divided, such a semiconductor device is easily manufactured and a yield is improved, and the number of components and the number of processes are reduced, thus reduction of manufacturing cost of the semiconductor device can be expected. The structure of the semiconductor device is simplified, thus such a configuration can contribute to increase of reliability of the semiconductor device.

### Embodiment 4

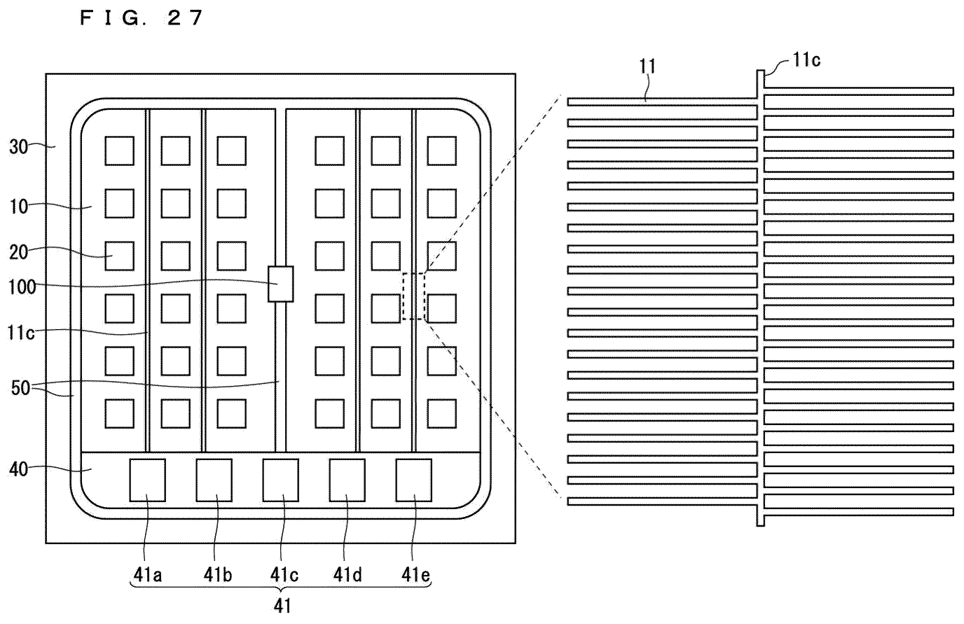

FIG. 27 is a diagram for explaining a configuration of a semiconductor device according to an embodiment 4. In the semiconductor device 101 according to the embodiment 1, all of the plurality of active trench gates 11 extend to the same direction (this direction is defined as “the first direction”) in the IGBT region 10 as illustrated in FIG. 5. In contrast, in the semiconductor device 101 according to the embodiment 4, as illustrated in FIG. 27, the IGBT region 10 includes an active trench gate 11c (referred to as “the intersection trench gate 1C” hereinafter) extending to a second direction perpendicular to the first direction in addition to the active trench gate 11 extending to the first direction.

The intersection trench gate 11c extends to an outer surrounding part of the chip, and is electrically connected to a gate wiring (not shown) disposed in the gate wiring region 50 on the outer surrounding part of the effective region. Each active trench gate 11 is connected to the intersection trench gate 11c to have a T-like shape. The other configuration thereof is similar to that of the embodiments 1 to 3.

According to the semiconductor device 101 of the embodiment 4, obtained is an effect of being able to suppress increase of a gate delay time in addition to the effect similar to that of the embodiments 1 to 3. As a result, ununiformity of current in a surface caused by a cell delayed in operation is suppressed, thus reduction of the temperature (Tj) of the topmost surface of the chip and improvement of a short-circuit withstand time can be expected compared with the embodiments 1 to 3. The active trench gate 11 and the intersection trench gate 11c are connected to each other to have the T-like shape, thus deterioration of embedding properties of the gate trench electrode 11a in a part where the active trench gate 11 and the intersection trench gate 11c are connected can be suppressed.

### Embodiment 5

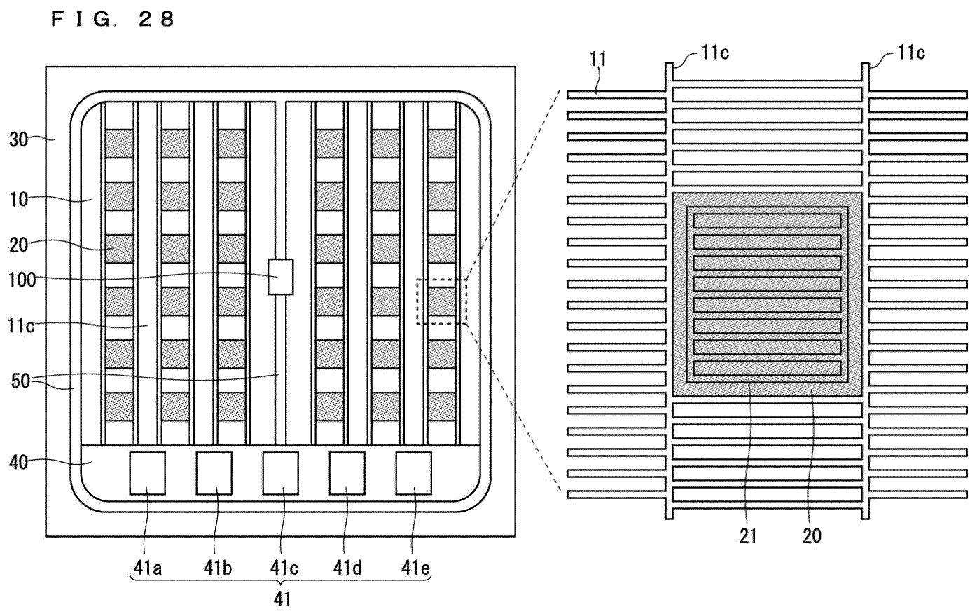

FIG. 28 is a diagram for explaining a configuration of a semiconductor device according to an embodiment 5. In FIG. 28, a hatching of a sand-like pattern is applied to the diode region 20 to easily recognize a position of the diode region 20.

In the semiconductor device 101 according to the embodiment 5, the intersection trench gate 11c is disposed along an end portion of diode region 20. That is to say, the intersection trench gate 11c extend along a side of the diode region 20. The other configuration thereof is similar to that of the embodiment 4.

According to the semiconductor device 101 of the embodiment 5, the effect similar to that of the embodiment 4 can be obtained while suppressing reduction of the effective region (increase in an ineffective region) caused by providing the intersection trench gate 11c to a minimum.

### Embodiment 6

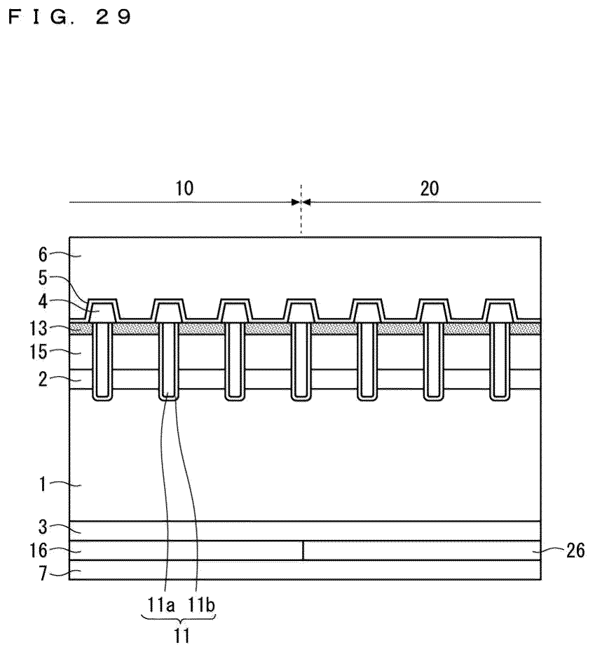

FIG. 29 is a cross-sectional view of a boundary between an IGBT region and a diode region in a semiconductor device according to an embodiment 6. As illustrated in FIG. 29, in the semiconductor device 101 according to the embodiment 6, a structure on the side of the first main surface of the semiconductor device 101 is the same between the diode region 20 and the IGBT region 10, and only a structure of the back surface side thereof is different therebetween. That is to say, in the semiconductor device 101 according to the embodiment 6, the active trench gate 11 to which the gate drive voltage is applied and the n⁺-type emitter layer 13 adjacent to the active trench gate 11 are formed also in the diode region 20 in the manner similar to the IGBT region 10.

Also in the semiconductor device 101 according to the embodiment 6, a length of the boundary between the IGBT region 10 and the diode region 20 can be increased, and local heat generation can be suppressed. Electrical power can be conducted in the whole chip, thus a current density can be lowered, and thus the effect of reduction of the temperature (Tj) of the topmost surface of the chip and improvement of a short-circuit withstand time can be expected compared with the embodiments 1 to 5.

Each embodiment can be arbitrarily combined, or each embodiment can be appropriately varied or omitted.

### APPENDIX

The aspects of the present disclosure are collectively described hereinafter as appendixes.

### Appendix 1

A semiconductor device, comprising
a chip of a reverse conducting IGBT (RC-IGBT) including:
an IGBT region functioning as an insulated gate bipolar transistor (IGBT); and
a plurality of diode regions functioning as a diode, wherein
the plurality of diode regions are disposed to form an island-like shape in an effective region which is a region made up of the IGBT region and the diode regions, and
when a length of one side of one of the diode regions is WD, an interval of the diode regions adjacent to each other is WI, a length of one side of the effective region is WC, and a thickness of the chip is t, satisfied are relationships of:

$$2 t < W D < 5 t ;$$

$$2 t < W I < 5 t ;$$

$$and WD + WI < WC / 6.$$

### Appendix 2

The semiconductor device according to Appendix 1, wherein
both the length of one side of one of the diode regions and the interval of the diode regions adjacent to each other are equal to or larger than 160 μm and equal to or smaller than 400 μm.

### Appendix 3

The semiconductor device according to Appendix 1 or 2, wherein
a gate wiring region where a gate wiring connecting a gate electrode of the IGBT and a gate pad is disposed is not provided in the effective region, but is provided to an outer surrounding part of the effective region.

### Appendix 4

The semiconductor device according to any one of Appendixes 1 to 3, wherein
each of the diode regions includes a trench gate extending to a first direction and an intersection trench gate extending to a second direction perpendicular to the first direction as an active trench gate in which a gate electrode of the IGBT is embedded, and
the intersection trench gate is connected to a gate wiring connecting the gate electrode of the IGBT and a gate pad in the outer surrounding part of the effective region.

### Appendix 5

The semiconductor device according to Appendix 4, wherein
the intersection trench gate extends along an end portion of each of the diode regions.

### Appendix 6

The semiconductor device according to any one of Appendixes 1 to 5, wherein
each of the diode regions and the IGBT region have a same structure on a side of a first main surface, and have structures different from each other on a side of a second main surface.

### Appendix 7

The semiconductor device according to any one of Appendixes 1 to 6, wherein
the chip further includes a temperature sensing diode disposed on an outer side of the effective region in a plan view.

### Appendix 8

The semiconductor device according to any one of Appendixes 1 to 7, wherein
the chip further includes a laminated metal layer including a metal layer disposed on an upper side of the effective region and a plating layer on the metal layer.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising
a chip of a reverse conducting IGBT (RC-IGBT) including:
an IGBT region functioning as an insulated gate bipolar transistor (IGBT); and
a plurality of diode regions functioning as a diode, wherein
the plurality of diode regions are disposed to form an island-like shape in an effective region which is a region made up of the IGBT region and the diode regions, and
when a length of one side of one of the diode regions is WD, an interval of the diode regions adjacent to each other is WI, a length of one side of the effective region is WC, and a thickness of the chip is t, satisfied are relationships of:
$$2 t < W D < 5 t ;$$
$$2 t < W I < 5 t ;$$
$$and WD + WI < WC / 6.$$

2. The semiconductor device according to claim 1, wherein
both the length of one side of one of the diode regions and the interval of the diode regions adjacent to each other are equal to or larger than 160 μm and equal to or smaller than 400 μm.

3. The semiconductor device according to claim 1, wherein
a gate wiring region where a gate wiring connecting a gate electrode of the IGBT and a gate pad is disposed is not provided in the effective region, but is provided to an outer surrounding part of the effective region.

4. The semiconductor device according to claim 1, wherein
each of the diode regions includes a trench gate extending to a first direction and an intersection trench gate extending to a second direction perpendicular to the first direction as an active trench gate in which a gate electrode of the IGBT is embedded, and
the intersection trench gate is connected to a gate wiring connecting the gate electrode of the IGBT and a gate pad in the outer surrounding part of the effective region.

5. The semiconductor device according to claim 4, wherein
the intersection trench gate extends along an end portion of each of the diode regions.

6. The semiconductor device according to claim 1, wherein
each of the diode regions and the IGBT region have a same structure on a side of a first main surface, and have structures different from each other on a side of a second main surface.

7. The semiconductor device according to claim 1, wherein
the chip further includes a temperature sensing diode disposed on an outer side of the effective region in a plan view.

8. The semiconductor device according to claim 1, wherein
the chip further includes a laminated metal layer including a metal layer disposed on an upper side of the effective region and a plating layer on the metal layer.
